(19) United States
(12) Patent Application Publication
(10) Pub. No.: US 2022/0208287 A1
(43) Pub. Date: Jun. 30, 2022

(54) SYSTEM AND METHODS FOR PROGRAMMING NONVOLATILE MEMORY

(71) Applicant: SanDisk Technologies LLC, Addison, TX (US)

(72) Inventors: Akshay Petkar, Bengaluru (IN); Rangarao Samineni, Bengaluru (IN); Satish Ganta, Bengaluru (IN)

(73) Assignee: SanDisk Technologies LLC, Addison, TX (US)

(21) Appl. No.: 17/136,441

(22) Filed: Dec. 29, 2020

(51) Int. Cl. G11C 16/34; G11C 16/04; G11C 16/10

(52) U.S. Cl. CPC G11C 16/3459; H01L 27/11556; G11C 16/10; G11C 16/0483

(57) ABSTRACT

Apparatus and methods are described to program memory cells and verify stored values programmed into the cells. A verify operation can be modified to reduce the time spent to verify the state of memory cells. A scan operation operates to determine the state of a memory cell of group of memory cells being part of a verify in programming, e.g., during a programming loop. A scan operation can determine the cell voltage level, e.g., the low voltage (VL). The scan operation can determine if the cell is in a quick pass write state, e.g., the cells with their voltage (Vth) between the VL and VH. The detect operation determines whether the subsequent VL sensing and verification is to be skipped based on the count of memory cells that exceed VL and those in QPW.

### BACKGROUND

The present technology relates to the operation of memory devices.

Semiconductor memory devices have become more popular for use in various electronic devices, such as cellular telephones, digital cameras, personal digital assistants, mobile computing devices, non-mobile computing devices and other devices. A non-volatile memory allows information to be stored and retained even when the non-volatile memory is not connected to a source of power (e.g., a battery). There is a continuing need for improved efficiency and speed of operation in non-volatile memory.

### SUMMARY

Various embodiments are described herein for operating a nonvolatile memory, e.g., a NAND, a BICOS memory or the like. A memory can include a memory control circuitry and a plurality of memory cells to store data operable connected to the memory control circuitry. The memory control circuitry is configured to: skip subsequent program verify operation s if at least one low voltage verify skip criterion is met. The criterion can be the voltage at the memory cell is greater than a low voltage level or the memory cell has entered a quick pass write state, e.g., the voltage level of the memory cell is greater than the low voltage level and less than a high voltage level. The high voltage level can be the programmed value for the memory cell.

In an example embodiment, a memory apparatus can include a plurality of volatile memory cells configured to be programmed to multiple states and a memory controller operably connected to the plurality of memory cells and configured to: program the plurality of memory to at least one of the multiple states; and verify a state of the programmed memory cells. The controller's verify operation can include a scan operation of the plurality of memory cells to detect the voltage level of the cell, and a comparing operation for the scanned voltage level against a low voltage verify skip criterion for at less than a high voltage level and if the low voltage verify skip criterion is met stop verify for the low voltage and continue verify for a high voltage criterion, and if the low voltage verify skip criterion is not met continue verify for the low voltage.

In an example embodiment, the low voltage verify skip criterion includes the sensed voltage of the memory cell being less than a VL level in the to be programmed memory cell.

In an example embodiment, the memory controller is configured to program the plurality of memory cells at any of the multiple states to store data therein using multiple programming loops and to skip subsequent program loops after the low voltage verify skip criterion is met.

In an example embodiment, the memory controller is configured to skip subsequent program loops to save time in programming time (tPROG for the entire memory programming operation) by not performing low voltage verify when the low voltage verify skip criterion is met or wherein the low voltage verify skip reduces tPROG by at least 10 μs per state.

In an example embodiment, the low voltage verify skip criterion includes the sensed voltage of the memory cell being in a quick pass write level.

In an example embodiment, the low voltage verify skip criterion is the sensed voltage of the memory cell being greater than low voltage VL of the program state and less than the high voltage VH of program state.

In an example embodiment, the memory controller is configured to program the plurality of memory cells at any of the multiple states to store data therein using multiple programming loops and to skip subsequent program loops after the low voltage verify skip criterion is met.

In an example embodiment, the memory controller is configured to skip subsequent program loops to save time in tPROG by not performing low voltage verify when the low voltage verify skip criterion is met.

In an example embodiment, the low voltage verify skip reduces tPROG by at least 10 μs per state.

In an example embodiment, the memory controller skips a last programming loop of each memory cell state during verify.

In an example embodiment, the memory controller is configured to conduct a bit scan pass fail rate on the programmed memory cells after the low voltage verify skip is triggered or the memory cells are all fully programmed.

A nonvolatile memory control method is described herein and may comprise: programming memory cells to a state; verifying stored values programmed into the memory cells including: detecting a low voltage sensing count from the memory cells being programmed with the low voltage being as a low tail of a voltage distribution for the state; and comparing the low voltage sensing count to a low voltage verify skip criterion when the criterion is not met moving on to the next programming loop with no verification change and when the criterion is met moving on to the next programming loop with and skipping any subsequent low voltage verify and using high voltage verifying in place of detecting the low voltage sensing count.

In an example embodiment, detecting includes detecting quick-pass-write cells from the memory cells to produce a quick-pass-write cell count to be used as the low voltage sensing count.

In an example embodiment, the low voltage skip criterion is a number of cells in the quick pass write level and when the low voltage sensing count meets or exceeds number of cells in the quick pass write level, then the criterion is met.

In an example embodiment, verifying includes conducting a pass fail bit scan verify after the high voltage verifying.

In an example embodiment, detecting includes detecting low voltage cells from the memory cells with voltage level less than a state low voltage and wherein comparing includes the criterion being a number of memory cells being below a low voltage tail for a program state.

In an example embodiment, skipping any subsequent low voltage verify includes skipping verify of at least a last programming loop for two or more programming loops for a single memory cell programming state.

A further nonvolatile memory program verify method is described herein and may comprise: programming memory cells to a state; and verifying the state of the programmed memory cells. In an example embodiment, verifying the state of the programmed memory cells includes: scanning the plurality of memory cells to detect the voltage level of the memory cells; comparing the scanned voltage level against a low voltage verify skip criterion for at less than a high voltage level; counting a number of memory cells that pass the low voltage verify skip criterion to produce a low voltage verify skip count for the state; and comparing the low voltage verify skip count to a count threshold and if the low voltage verify count is less than the count threshold, stop verifying memory cell program for the low voltage and continuing verify for a high voltage.

In an example embodiment, verifying the state of the programmed memory cells includes continuing to verifying for both for the low voltage and the high voltage when the count threshold is exceeded.

In an example embodiment, verifying the state of the programmed memory cells includes skipping verify of at least a last programming loop for two or more programming loops for a single memory cell programming state.

The example embodiments described in this section can be combined with each other in any order.

### BRIEF DESCRIPTION OF THE DRAWINGS

A more particular description is included below with reference to specific embodiments illustrated in the appended drawings. Understanding that these drawings depict only certain embodiments of the disclosure and are not, therefore, to be considered limiting of its scope, the disclosure is described and explained with additional specificity and detail through the use of the accompanying drawings, in which:

FIG. 1 illustrates an embodiment of an array of memory cells including bit and word lines according to an example embodiment;

FIG. 2 is a diagram of a three-dimensional (3D) memory in a NAND configuration according to an example embodiment;

FIG. 3 is a schematic block diagram illustrating an embodiment of a 3D vertical memory structure according to an example embodiment;

FIG. 4 is a diagram showing a top view of a 3D memory block according to an example embodiment;

FIG. 5 illustrates an array of sense amplifier groups according to an exemplary embodiment for the 3D memory block of FIG. 4;

FIG. 6 is a schematic block diagram illustrating an embodiment of a memory system according to an example embodiment;

FIG. 7 is a schematic block diagram of non-volatile storage device for memory cell subgroup identification and selection;

FIG. 8 illustrates a program verify operation according to an example embodiment;

FIG. 9 illustrates a flow chart of a program verify operation according to an example embodiment;

FIG. 10 illustrates a flow chart of a program verify operation according to another example embodiment;

FIG. 11 illustrates a flow chart of a program verify operation according to yet another example embodiment;

FIG. 12 is a programming diagram that shows all of the program and verify operations for the programming of states S1-S14;

FIG. 13 shows a graph of programming states of a plurality of memory cells;

FIG. 14 shows a graph of programming states of a plurality of memory cells; and

FIG. 15 shows a graph of programming states of a plurality of memory cells.

### DETAILED DESCRIPTION

Systems and methods are described for controlling the program operations of nonvolatile memory to improve speed of operation by triggering skip of some program operations. When programming a memory (e.g., a nonvolatile memory, such as NAND), an ever-increasing number of memory cells can move into a quick pass write (QPW) with each programming loop. This may be true for each program state. It has been found that for the last few program loops, most of the cells of interest for a given state are in QPW and low voltage (VL) verify for that state is not necessary during program voltage verify. As a result of the state of the memory cells, programming time (tPROG) can be improved by identifying and skipping the redundant VL verify operations.

In an example embodiment, a memory controller can create scan operations to identify cells that meet certain condition parameters. The condition parameters can be QPW or with the threshold voltage (Vt) less than the VL. The number of memory cells that meet the scan operation parameters can be counted to produce a count. The count is compared against a criterion of low voltage scan verify (VLVS). For the counts that pass the VLVS criterion, then subsequent VL sensing is skipped.

In an example embodiment, the memory controller can have a detect algorithm to implement scanning memory cell states, tagging the cells that meet a criterion, counting the tagged cells, and then skipping subsequent verify operations on those cells.

A programming operation for a group of memory cells typically involves providing the memory cells in an erased state and then applying a series of program pulses to the memory cells. Each program pulse is provided in a program loop, also referred to as a program-verify iteration. For example, the program pulse may be applied to a word line that is connected to control gates of the memory cells. In one approach, incremental step pulse programming is performed, in which the program pulse amplitude is increased by a step size in each program loop. Verify operations may be performed after each program pulse to determine whether the memory cells have completed programming. When programming has completed for a memory cell, the memory cell can be locked out from further programming while programming continues for other memory cells in subsequent program loops. Subsequent verify steps can be skipped when the current verify operation confirms that the memory cells are in a QPW and with the low voltage greater than the threshold voltage.

Each memory cell may be associated with a memory state according to write data in a program command. As used herein, a “memory state” is a detectable characteristic of a memory cell (e.g., a threshold voltage of a NAND memory cell, a resistance of a ReRAM memory cell, a magnetization state of a magnetoresistive random access memory) that may be used to represent a data value, such as a binary data value, including more than one binary bit. As used herein, the detectable characteristic of a memory cell used to represent a data value is referred to as a “programming characteristic.” Based on write data in a program command, a memory cell will either remain in the erased state or be programmed to a memory state (a programmed memory state) different from the erased state. The detected voltage in the cell can determine its state.

For example, in a two-bit per cell memory device, there are four memory states including the erased state and three programmed memory states. In a three-bit per cell memory device, there are eight memory states including the erased state and seven programmed memory states. In a four-bit per cell memory device, there are sixteen memory states including the erased state and fifteen programmed memory states. These states can be set by programming a voltage level into the cell.

When a program command is issued, the write data are stored in data latches associated with the memory cells. For example, in a two-bit per cell memory device, each memory cell is associated with two data latches (e.g., DL1, DL2) that store the two-bit write data for the memory cell. Likewise, in a three-bit per cell memory device, each memory cell is associated with three data latches (e.g., DL1, DL2, DL3) that store the three-bit write data for the memory cell. Similarly, in a four-bit per cell memory device, each memory cell is associated with four data latches (e.g., DL1, DL2, DL3, DL4) that store the four-bit write data for the memory cell. Examples of data latches can be found in U.S. Pat. No. 10,535,401, which is incorporated by reference herein.

During programming, the data latches of a memory cell can be read to determine the memory state to which the cell is to be programmed. For NAND memory cells, each programmed memory state is associated with a verify voltage. A NAND memory cell with a given memory state is considered to have completed programming when a sensing operation determines the threshold voltage (Vt) of the memory cell is above the associated verify voltage. A sensing operation can determine whether a memory cell has a Vth above the associated verify voltage by applying the associated verify voltage to the control gate and sensing a current through the memory cell. If the current is relatively high, this indicates the memory cell is in a conductive state, such that the Vt is less than the control gate voltage. If the current is relatively low, this indicates the memory cell is in a non-conductive state, such that the Vt is above the control gate voltage.

In addition to the verify operations described above, a bitscan operation also may be performed to determine when programming is complete for a group of memory cells. As used herein, a “bitscan” is an operation that counts a number of memory cells whose programming characteristic has not shifted above a particular verify voltage level for a particular memory state. For NAND memory cells, a bitscan is an operation that counts a number of memory cells whose threshold voltage has not shifted above a particular verify voltage level for a particular memory state. For example, a state N bitscan is a count of a number of state N memory cells whose threshold voltage has not shifted above a verify voltage level for state N. Likewise, a state (N+1) bitscan is a count of a number of state (N+1) memory cells whose threshold voltage has not shifted above a verify voltage level for state (N+1), and so on. For simplicity, the following discussion will refer to bitscan operations for NAND memory cells although bitscan operations also may be used for other non-volatile memory technologies. According to embodiments of the present disclosure these bitscan counts to trigger the verify operation to skip to the next program level in the same programming loop or program verify in subsequent program loops. The verify voltage can be a low voltage value or a high voltage level with the low voltage level being less than the high voltage level. Verification of the memory cells can be considered complete when a count of memory cells in a QPW state exceeds a first threshold count value and when a low voltage level verify count exceeds a second threshold count value.

Programming of memory cells for a particular memory state may be considered complete if the bitscan count for a particular state is less than a predetermined value. In some embodiments, the predetermined value is less than a number of read errors that can be corrected by an error correction code engine. In other words, programming of memory cells for a particular memory state may be considered complete even though all memory cells that are to be programmed to the particular memory state do not have threshold voltages (Vt) that have shifted above a verify voltage level for the memory state, as long as the number of “failing” memory cells is less than a number of read errors that can be corrected by an error correction code engine. Moreover, the count of memory cells can be used to trigger a skip to the next memory state verify operation.

Bitscan calculations typically are performed based on results of verify operations for a particular program-verify iteration. In particular, following application of a program pulse, verify operations may be performed for one or more memory states, and then the results of the verify operations may be used to calculate the bitscan for a particular memory state.

In some programming techniques, following each program pulse, a bitscan is performed for a single memory state (a “single-state bitscan”), and bitscans for higher memory states are not performed until the bitscan count for the lower memory state is less than the threshold value. Under some circumstances, performing such single-state bitscans may result in extra verify operations being performed and extra program pulses being applied to the memory cells, even though the memory cells have actually completed programming. This is undesirable because time is consumed performing verify operations, and applying unnecessary program pulses may cause program disturb.

In other programming techniques, following each programming pulse, a bitscan is performed for multiple (e.g., n) consecutive memory states (an “n-state bitscan”). Under some circumstances, performing such n-state bitscans also may result in extra verify operations being performed and extra program pulses being applied to the memory cells, even though the memory cells have actually completed programming. As in the case of single-state bitscans, this is undesirable because time is consumed performing verify operations, and applying unnecessary program pulses may cause program disturb. Technology is described herein which can perform an n-state bitscan to perform program verify for more than one memory state in a single iteration, e.g., when the bit count for a lower state exceeds a threshold value.

In example embodiments described herein time savings can be achieved by skipping subsequent verify operations when the memory cells meet at least one criterion. One criterion can be the number of memory cells that have passed to a QPW state. Another criteria can be the number of cells that have been verified to be a low voltage (VL) level. When these occur a low voltage verify skip criterion has been met. This can trigger the memory to skip VL sensing thereafter.

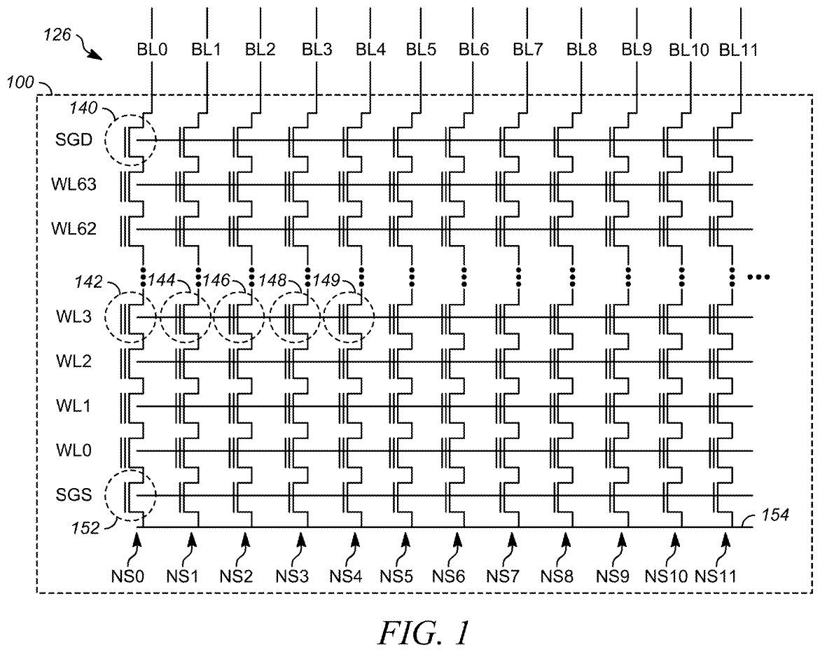

FIG. 1 depicts an embodiment of memory arranged as NAND flash memory cells in a memory array 126. As used herein, the term “memory” denotes semiconductor memory. Types of semiconductor memory include volatile memory and non-volatile memory. Non-volatile memory allows information to be stored and retained even when the non-volatile memory is not connected to a source of power (e.g., a battery). Examples of non-volatile memory include flash memory (e.g., NAND-type and NOR-type flash memory), Electrically Erasable Programmable Read-Only Memory (EEPROM), ferroelectric memory (e.g., FeRAM), magnetoresistive memory (e.g., MRAM), spin-transfer torque magnetic random access memory (STT-RAM or STT-MRAM), resistive random access memory (e.g., ReRAM or RRAM) and phase change memory (e.g., PRAM or PCM). Non-volatile memory can be BiCS memory architecture. Non-volatile memory includes one or more memory cells. A “memory cell” is an electronic device or component capable of storing electronic information. In an embodiment, non-volatile memory utilizes floating-gate transistors or charge trap transistors as memory cells. The ability to adjust the threshold voltage of a floating-gate transistor or charge trap transistor allows the transistor to act as a non-volatile storage element or memory cell, such as a single-level cell (SLC). However, in some cases more than one data bit per memory cell (e.g., a multi-level cell) can be provided by programming and reading multiple threshold voltages or threshold voltage ranges, including a multi-level cell (MLC) (2 bits-per-cell), a triple level cell (TLC) (3 bits-per-cell), a quad-level cell (QLC) (4 bits-per-cell), and so forth.

The memory array 126 can include many blocks of memory. A “block of memory” is a set of memory cells. For example, a block of memory (e.g., an array of memory cells) includes memory cells arranged in word lines and bit lines. A “sub-block” of memory is a subset of a block of memory. A block of memory includes two or more sub-blocks. For instance, a sub-block is a subset of memory cells corresponding to a subset of the word lines of a block of memory. In an embodiment, a sub-block includes fifty word lines in a block of memory, where the block of memory includes more than fifty word lines. A sub-block can denote a physical sub-block, a logical sub-block, or both. In an embodiment, memory is structured as two-dimensional (2D) NAND. In another embodiment, memory is structured as three-dimensional (3D) NAND. In an embodiment, one or more of the components described herein (e.g., memory die, memory, block, sub-block, memory cells, circuits, controllers, and/or non-volatile storage systems) are implemented with one or more elements (e.g., transistors, resistors, capacitors, inductors, and/or conductors) in integrated circuitry.

An illustrative block of memory (or block) 100, as shown in FIG. 1, includes a number of NAND strings NS0 to NS11 and respective bit lines (e.g., BL0 to BL11, which are shared among the blocks). Each NAND string is connected at one end to a drain select gate (SGD), and the control gates of the drain select gates are connected via a common SGD line. Each NAND string is connected at its other end to a source select gate (SGS) which, in turn, is connected to a common source line 154. For example, NS0 includes a source side select gate transistor 152 and a drain side select gate transistor 140. Example storage elements 142, 144, 146, 148, and 149 are in NS0 to NS4, respectively, and are connected to a word line WL3. For example, WL3 could be a selected word line which is selected for programming and the example storage elements can be selected storage elements which are selected for programming. Other storage elements connected to WL3 can also be selected storage elements. Sixty-four word lines, for example, WL0-WL63, extend between the source-side select gates and the drain-side select gates.

Other types of non-volatile memory in addition to NAND flash memory can also be used. For example, another type of memory cell useful in flash EEPROM systems utilizes a nonconductive dielectric material in place of a conductive floating gate to store charge in a nonvolatile manner. In an embodiment, triple layer dielectric formed of silicon oxide, silicon nitride, and silicon oxide (ONO) is sandwiched between a conductive control gate and a surface of a semi-conductive substrate above the memory cell channel. The cell is programmed by injecting electrons from the cell channel into the nitride, where they are trapped and stored in a limited region. This stored charge then changes the voltage level of a portion of the channel of the cell in a manner that is detectable. The cell is erased by injecting hot holes into the nitride. A similar cell can be provided in a split-gate configuration where a doped polysilicon gate extends over a portion of the memory cell channel to form a separate select transistor. Another type of memory uses a metallic (conductive) charge storage element in a NAND architecture.

In another approach, NROM cells are used. Two bits, for example, are stored in each NROM cell, where an ONO dielectric layer extends across the channel between source and drain diffusions. The charge for one data bit is localized in the dielectric layer adjacent to the drain, and the charge for the other data bit is localized in the dielectric layer adjacent to the source. Multi-state data storage is obtained by separately reading binary states of the spatially separated charge storage regions within the dielectric. Other types of non-volatile memory are also known. In an alternative embodiment, resistance levels rather than threshold voltage levels can be stored and sensed.

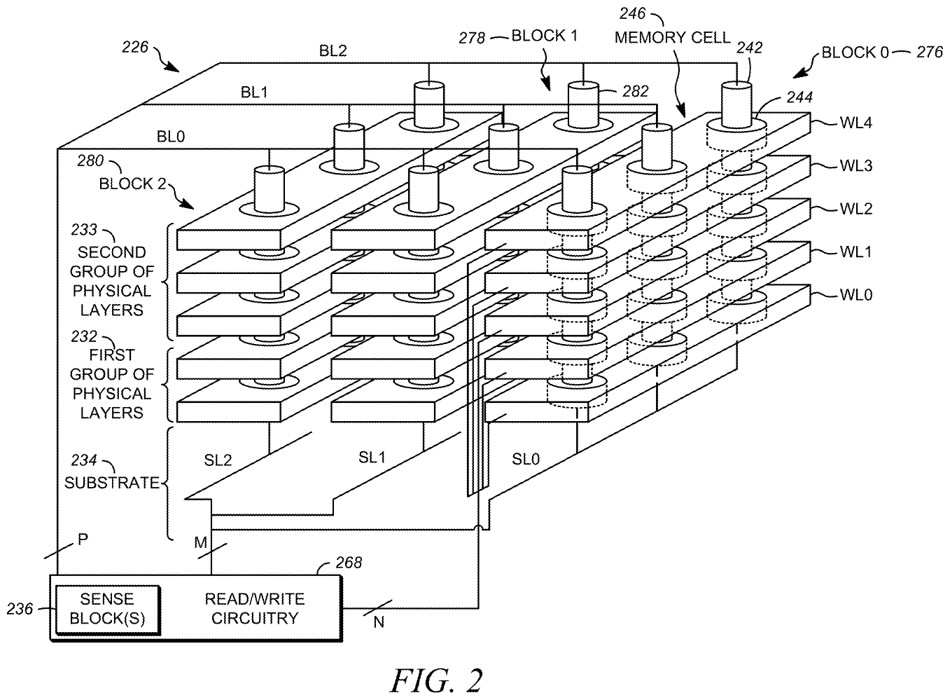

FIG. 2 illustrates an embodiment of 3D memory 226 in a NAND flash configuration. The 3D memory 226 includes multiple physical layers that are monolithically formed above a substrate 234, such as a silicon substrate. Storage elements (e.g., memory cells), such as a representative memory cell 246, are arranged in arrays in the physical layers.

The representative memory cell 246 includes a charge trap structure 244 between a word line/control gate WL4 and a conductive channel 242. Charge can be injected into or drained from the charge trap structure 244 via biasing of the conductive channel 242 relative to the word line WL4. For example, the charge trap structure 244 can include silicon nitride and can be separated from the word line WL4 and the conductive channel 242 by a gate dielectric, such as a silicon oxide. An amount of charge in the charge trap structure 244 affects an amount of current through the conductive channel 242 during a read operation of the memory cell 246 and indicates one or more bit values that are stored in the memory cell 246. The charge trap structure can determine the voltage level that will be verified in some embodiments of the present disclosure.

The 3D memory 226 includes multiple erase blocks, including a first block (block 0) 276, a second block (block 1) 278, and a third block (block 2) 280. Each block 276, 278, 280 includes a “vertical slice” of the physical layers that includes a stack of word lines, illustrated as a first word line WL0, a second word line WL1, a third word line WL2, a fourth word line WL3, and a fifth word line WL4. Multiple conductive channels (having a substantially vertical orientation, as shown in FIG. 2) extend through the stack of word lines. Each conductive channel is coupled to a storage element in each word line WL0-WL4, forming a NAND string of storage elements. FIG. 2 illustrates three blocks 276, 278, 280, five word lines WL0-WL4 in each block 276, 278, 280, and three conductive channels in each block 276, 278, 280 for clarity of illustration. However, the 3D memory 226 can have more than three blocks, more than five word lines per block, and more than three conductive channels per block.

Read/write circuitry 268 (which can be part of a controller) is coupled to the conductive channels via multiple conductive lines, illustrated as a first bit line BL0, a second bit line BL1, and a third bit line BL2 at a first end of the conductive channels (e.g., an end most remote from the substrate 234) and a first source line SL0, a second source line SL1, and a third source line SL2 at a second end of the conductive channels (e.g., an end nearer to or within the substrate 234). The read/write circuitry 268 is illustrated as coupled to the bit lines BL0-BL2 via “P” control lines, coupled to the source lines SL0-SL2 via “M” control lines, and coupled to the word lines WL0-WL4 via “N” control lines. Each of P, M, and N can have a positive integer value based on the specific configuration of the 3D memory 226. In the example shown in FIG. 2, P=3, M=3, and N=5.

In a particular embodiment, each of the bit lines BL0-BL2 and each of the source lines SL0-SL2 can be coupled to the same end (e.g., the first end or the second end) of different conductive channels. For example, a particular bit line BL0-BL2 can be coupled to a first end of a conductive channel 282, and a particular source line can be coupled to a first end of the conductive channel 242. A second end of the conductive channel 282 can be coupled (e.g., electrically coupled) to a second end of the conductive channel 242. Accordingly, the conductive channel 282 and the conductive channel 242 can be coupled in series and can be coupled to the particular bit line BL0-BL2 and the particular source line SL0-SL2, each of which is coupled to a particular NAND string.

Although each of the conductive channels, such as the conductive channels 242, 282, is illustrated as a single conductive channel, each of the conductive channels can include multiple conductive channels that are in a stack configuration. The multiple conductive channels in a stacked configuration can be coupled by one or more connectors. Additionally, an etch stop layer (not illustrated in FIG. 2) having a conductive connector coupled to physically proximate portions of a conductive channel can be included in the multiple conductive channels, such as between the first group of physical layers 232 and the second group of physical layers 233. Additionally, or alternatively, one or more sub-block gate transistors (not illustrated in FIG. 2) can be coupled between the first group of physical layers 232 and the second group of physical layers 233.

In an embodiment, the first group of physical layers 232 is an example of a first sub-block and the second group of physical layers 233 is an example of a second sub-block. For example, each sub-block (e.g., “word line-based” sub-blocks) can include memory cells corresponding to a subset of word lines WL0-WL4. In an alternative embodiment, each sub-block (e.g., “string-based” sub-blocks) can include memory cells corresponding to a subset of strings (e.g., NAND strings), and can have, for example, common source lines SL0-SL2, but not common bit lines BL0-BL2 or vice versa.

The read/write circuitry 268 facilitates and/or effectuates read and write operations performed on the 3D memory 226. For example, data can be stored to storage elements coupled to a word line WL0-WL4 and the read/write circuitry 268 can read bit values from the storage elements (e.g., memory cells) using one or more sense blocks 236. As another example, the read/write circuitry 268 can apply selection signals to control lines coupled to the word lines WL0-WL4, the bit lines BL0-BL2, and the source lines SL0-SL2 to cause a programming voltage (e.g., a voltage pulse or series of voltage pulses) to be applied across selected storage element(s) of the selected word line (e.g., the fourth word line WL4). The read/write circuitry 226 can also perform verify operations as part of the programming operation.

The read/write circuitry 268 includes one or more sense blocks 236. The sense blocks 236 are utilized to read or sense one or more values stored in a memory cell. In one approach, one sense block 236 is provided for a group of NAND strings, each of which is coupled to a particular bit line BL0-BL2. For example, a sense block 236 is associated with BL0. Another sense block 236 is associated with BL1, and yet another sense block 236 is associated with BL2. Each sense block 236 can include a memory controller (not illustrated in FIG. 2). Each sense block 236 also includes a sense module for each NAND string. Alternatively, a sense block 236 can be coupled to an interval of bit lines, such as even or odd numbered bit lines. The sense blocks can be used to sense the voltage level in a sell. When the memory controller determines that subsequent sense operations are to be skipped, these sense blocks need not be energized or read during the skipped time periods.

During a read operation, a controller can receive a request from a host device, such as a computer, smartphone, or laptop computer. The controller can cause the read/write circuitry 268 to read bits from particular storage elements of the 3D memory 226 by applying appropriate signals to the control lines to cause storage elements of a selected word line to be sensed. Accordingly, the 3D memory 226 having multiple conductive channels in a stacked configuration can be configured to read from and write data to one or more storage elements.

One or more sub-blocks of memory cells 246 in an array of memory cells 246 can be coupled by a channel (e.g., a physical communication channel). In an embodiment, the channel comprises a bit line BL0-BL2 and/or a source line SL0-SL2.

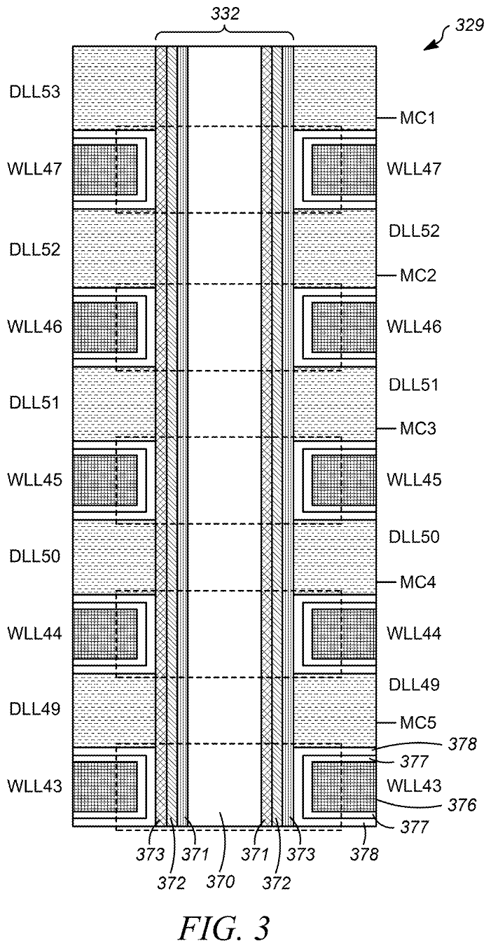

FIG. 3 illustrates one embodiment of a cross-sectional view of a 3D, vertical memory structure or string 329. In one embodiment, the vertical column 332 is round and includes four layers; however, in other embodiments more or fewer than four layers can be included, and other shapes can be used (e.g., a “U” shape instead of an “I” shape or the like). In one embodiment, a vertical column 332 includes an inner core layer 370 that is made of a dielectric, such as SiO2. Other materials can also be used. Surrounding the inner core or inner core layer 370 is a polysilicon channel 371. Materials other than polysilicon can also be used. Note that it is the channel 371 that connects to the bit line. Surrounding the channel 371 is a tunneling dielectric 372. In one embodiment, the tunneling dielectric 372 has an ONO structure. Surrounding the tunneling dielectric 372 is a shared charge-trapping layer 373, such as (for example) Silicon Nitride. Other materials and structures can also be used. The technology described herein is not limited to any particular material or structure.

FIG. 3 depicts dielectric layers DLL49, DLL50, DLL51, DLL52, and DLL53, as well as word line layers WLL43, WLL44, WLL45, WLL46, and WLL47. Each of the word line layers includes a word line region 376 surrounded by an aluminum oxide layer 377, which is surrounded by a blocking oxide (SiO₂) layer 378. The physical interaction of the word line layers with the vertical column 332 forms the memory cells. Thus, a memory cell, in one embodiment, comprises the channel 371, tunneling dielectric 372, charge-trapping layer 373 (e.g., shared with other memory cells), blocking oxide layer 378, aluminum oxide layer 377, and the word line region 376. In some embodiments, the blocking oxide layer 378 and aluminum oxide layer 377 can be replaced by a single layer of material with insulating properties or by more than two layers of different material with insulating properties. Furthermore, the materials used are not limited to silicon dioxide (SiO₂) or aluminum oxide. For example, word line layer WLL47 and a portion of vertical column 332 comprise a memory cell MC1. Word line layer WLL46 and a portion of vertical column 332 comprise a memory cell MC2. Word line layer WLL45 and a portion of vertical column 332 comprise a memory cell MC3. Word line layer WLL44 and a portion of vertical column 332 comprise a memory cell MC4. Word line layer WLL43 and a portion of vertical column 332 comprise a memory cell MC5. In other architectures, a memory cell can have a different structure, however, the memory cell would still be the storage unit.

When a memory cell is programmed, electrons are stored in a portion of the charge-trapping layer 373 that is associated with the memory cell. These electrons are drawn into the charge-trapping layer 373 from the channel 371, through the tunneling dielectric 372, in response to an appropriate voltage on the word line region 376. The threshold voltage (Vt) of a memory cell is increased in proportion to the amount of stored charge. In one embodiment, the programming is achieved through Fowler-Nordheim tunneling of the electrons into the charge-trapping layer 373. During an erase operation, the electrons return to the channel 371 or holes are injected into the charge-trapping layer 373 to recombine with electrons. In one embodiment, erasing is achieved using hole injection into the charge-trapping layer 373 via a physical mechanism such as gate induced drain leakage (GIDL).

Storage cells in the same location or position in different memory structures 329 (e.g., different memory strings 329) on different bit lines, in certain embodiments, can be on the same word line. Each word line can store one page of data, such as when 1-bit of data is stored per cell (SLC); two pages of data, such as when 2-bits of data are stored per cell (MLC); three pages of data, such as when 3-bits of data are stored per cell (TLC); four pages of data, such as when 4-bits of data are stored per cell (QLC); or another number of pages of data.

In the depicted embodiment, a vertical, 3D memory structure 329 comprises an “I” shaped memory structure 329. In other embodiments, a vertical, 3D memory structure 329 can comprise a “U” shaped structure or can have another vertical and/or stacked architecture. In certain embodiments, four sets of strings 329 (e.g., four sets of 48 word lines, or another predefined number of word lines) can form an erase block, while in other embodiments, fewer or more than four sets of strings 329 can form an erase block. As can be appreciated, any suitable number of storage cells can be part of a single string 329. In one embodiment, a single string 329 includes forty-eight storage cells.

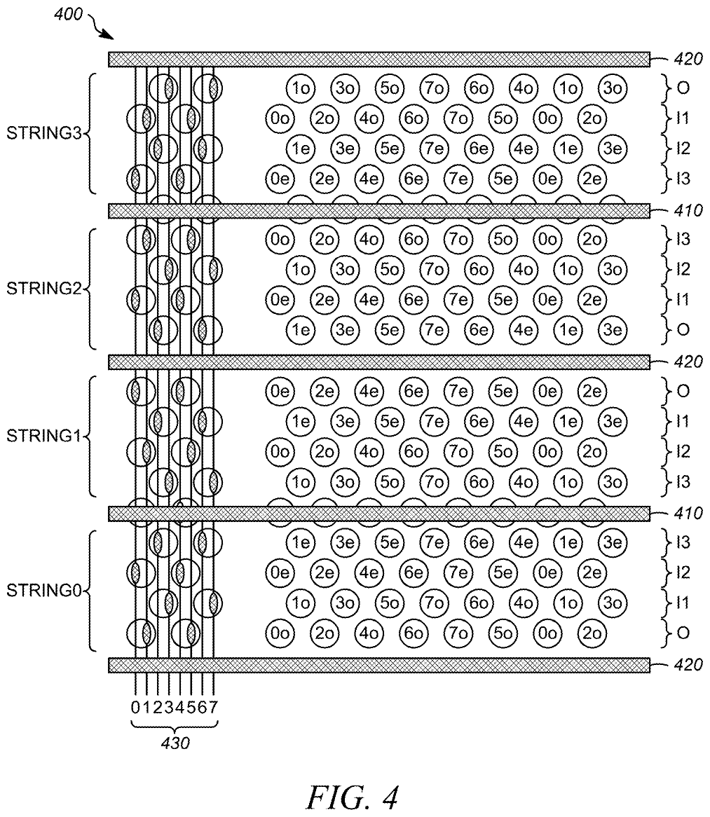

FIG. 4 is a diagram illustrating a top view of a 3D memory block 400, according to one embodiment. As illustrated, the 3D memory block 400 can comprise a series of memory holes or cells (represented by circles labeled “0o” to “7o” and “0e” to “7e” in FIG. 4). Each of these memory holes can be organized into strings (labeled as “String0” to “String3” in FIG. 4) and/or further organized into IO groups (labeled as “O,” “I1,” “I2,” and “I3” in FIG. 4). Each IO group is located between two different types of etching features formed in the 3D memory block 400, a shallow etching feature 410 (e.g., called SHE), and a deep etching feature 420 (e.g., called ST). The IO groups adjacent to a deep etching feature 420 are labeled Outer IO groups (O); the IO groups adjacent to a shallow etching feature 410 are labeled Inner3 IO groups (I3); the IO groups adjacent to the Outer IO groups are labeled Inner1 IO groups (I1); and the IO groups adjacent to the Inner3 IO groups (I3) are labeled Inner2 IO groups (12). It should be noted that the procedures and methods disclosed herein can be implemented in connection with a wide variety of types of memory, such as NAND or NOR memory, 2D memory, 3D memory, or memory employing a charge-based or resistive-based storage technology. In one example, the illustrated memory block 400 can comprise 16K memory cells, which can be further segregated into smaller groups of memory cells comprising 1K memory cells each. These smaller groups can be arranged in tiers. The tiers can include the memory cells associated with the holes designated by the same designated circles in FIG. 4. The memory cells labeled as 2o are part of a same tier. The memory cells labeled 3e are part another tier. The memory cells labeled as 2e are part of a same tier. The memory cells labeled 3o are part another tier. As explained herein the controller can select a single tier for a program verify operation when the program verify level is unlikely to find an overprogrammed state or when the single tier is representative of the other tiers. At least one intermediate level for program verify is a multiple tier verify operation.

Some manufacturing processes for 3D memory can include film deposition processes that tend to dominate over etching processes performed during manufacturing. For these types of manufacturing processes, the outer memory holes in the Outer IO groups (O) will generally program slower than the inner memory hole (I3). However, other manufacturing processes for 3D memory can include etching processes that tend to dominate over film deposition processes during manufacturing. For these types of manufacturing processes, the inner memory hole (I3) will generally program slower than the outer memory holes (O). It should be noted, however, that the physical position of an IO group of memory cells within the 3D memory structure is not always dispositive of its relative programming speed due to this variation introduced during the manufacturing process or as a result of wear induced by usage of the device. Moreover, cycling degradation can also cause the relative programming speed of different memory cells, or groups of memory cells, to shift over time.

Continuing with FIG. 4, each of the memory holes (0o-7o and 0e-7e) can be connected to bit lines 430 (labeled as bit lines 0-7 in FIG. 4). The bit lines 430 extend above the memory holes and are connected to select memory holes via connection points (illustrated as small, solid ovals in FIG. 4) indicating where a bit line 430 connects to a memory hole. For ease of illustration, only eight bit lines 430 (0 to 7) are shown in FIG. 4. However, it will be understood that other bit lines (not shown) also extend above the other memory holes in FIG. 4.

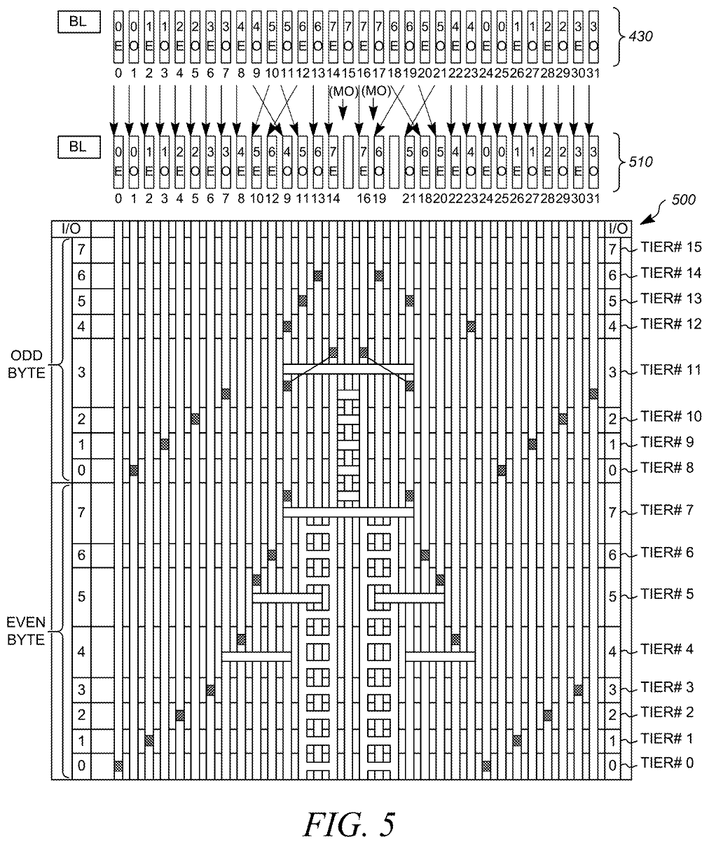

FIG. 5 illustrates an array of sense amplifier groups 500 for the 3D memory structure 400 of FIG. 4, according to an example. The bit lines 430 shown in FIG. 4 extend to the array of sense amplifier groups 500, as can be seen in FIG. 5. In this manner, certain memory holes of the 3D memory structure 400 can be electrically coupled to one of the bit lines 430, and each bit line 430 can then be electrically coupled to a bit line interface 510. In an embodiment, the bit line interface 510 can additionally use scrambling, as illustrated by the angled/non-vertical lines shown in FIG. 5 between the bit lines 430 and the bit line interface 510. Thereafter, each bit line 430 can be electrically coupled to a sense amplifier group (labeled as Tier #0 to Tier #15 in FIG. 5). As illustrated in FIG. 5, each sense amplifier group extends horizontally across the page. Accordingly, each “tier” comprises a group of memory holes in electrical communication with a particular sense amplifier group via a bit line 430. A tier can also be referred to as a “subgroup of memory cells,” or just a “subgroup.” A “subgroup” of memory cells can be any subset of memory cells formed from a larger group of memory cells. In this application, a subgroup of memory cells can be referred to as a tier, a tier group, an IO group, a division, and the like.

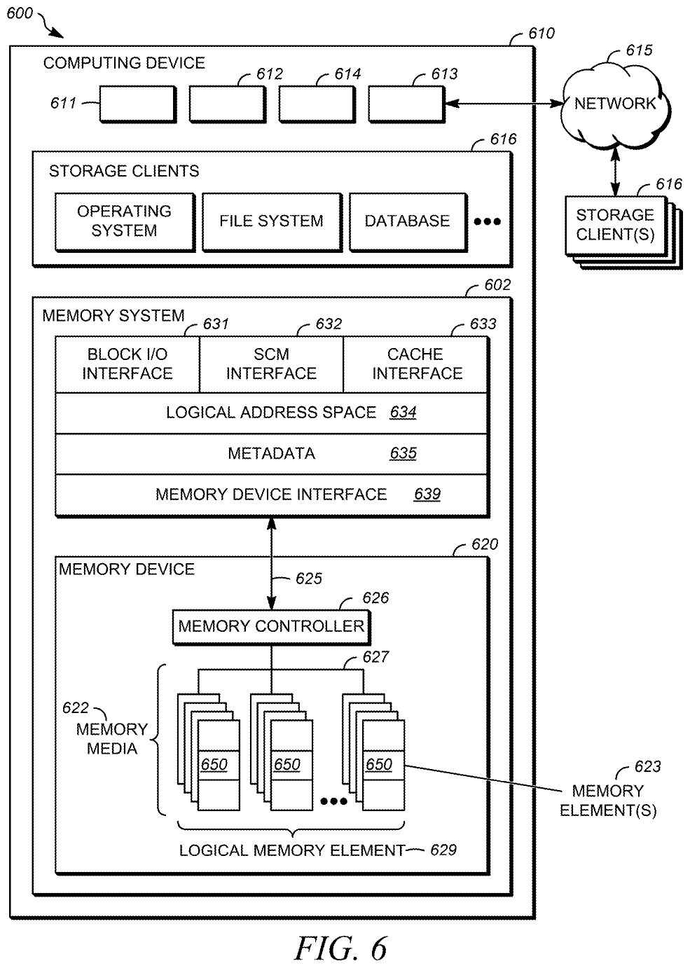

FIG. 6 is a schematic block diagram illustrating an embodiment of a system 600 and computing device 610 for memory cell subgroup identification and selection. The computing device 610 comprises one or more identification circuits or tier selection circuits 650 for memory media 622 of a non-volatile and/or volatile memory device 620. As used herein, a “tier circuit” refers to a circuit utilized to identify a particular tier of memory cells (e.g., a 2o tier) in relation to at least one other subgroup or tier of memory cells and select the identified tier of memory cells for use in at least one programming operation, e.g., program verify. The tier selection circuits 650 can operate to select a single tier for some program verify levels and multiple tiers for other program verify levels in a same verify operation. At least one verify is a single tier verify, e.g., the A or first program verify level. The first program verify level can be the lowest voltage. In an example embodiment, the last program verify level is also a single tier verify operation. In an example embodiment, at least one intermediate program verify is performed on multiple tiers.

A tier selection circuit 650 can be part of a non-volatile and/or volatile memory element 623 (e.g., disposed on a same integrated circuit device as a non-volatile memory media 622). In some embodiments, a memory device 620 can at least partially operate on and/or in communication with a nonvolatile and/or volatile memory system 602 of a computing device 610, which can comprise a processor 611, volatile memory 612, and a communication interface 613. The processor 611 can comprise one or more central processing units, one or more general-purpose processors, one or more application-specific processors, one or more virtual processors (e.g., the computing device 610 can be a virtual machine operating within a host), one or more processor cores, or the like. The communication interface 613 can comprise one or more network interfaces configured to communicatively couple the computing device 610 and/or memory controller 626 to a communication network 615, such as an Internet Protocol (IP) network, a Storage Area Network (SAN), wireless network, wired network, or the like.

The memory device 620, in various embodiments, can be disposed in one or more different locations relative to the computing device 610. In one embodiment, the memory device 620 comprises one or more non-volatile and/or volatile memory elements 623, such as semiconductor chips or packages or other integrated circuit devices disposed on one or more printed circuit boards, storage housings, and/or other mechanical and/or electrical support structures. For example, the memory device 620 can comprise one or more direct inline memory module (DIMM) cards, one or more expansion cards and/or daughter cards, a memory card, a universal serial bus (USB) drive, a solid-state-drive (SSD) or other hard drive device, and/or can have another memory and/or storage form factor. The memory device 620 can be integrated with and/or mounted on a motherboard of the computing device 610, installed in a port and/or slot of the computing device 610, installed on a different computing device 610 and/or a dedicated storage appliance on the network 615, in communication with the computing device 610 over an external bus (e.g., an external hard drive), or the like.

The memory device 620, in one embodiment, can be disposed on a memory bus of a processor 611 (e.g., on the same memory bus as the volatile memory 612, on a different memory bus from the volatile memory 612, in place of the volatile memory 612, or the like). In a further embodiment, the memory device 620 can be disposed on a peripheral bus of the computing device 610, such as a peripheral component interconnect express (PCI Express or PCIe) bus, a serial Advanced Technology Attachment (SATA) bus, a parallel Advanced Technology Attachment (PATA) bus, a small computer system interface (SCSI) bus, a FireWire bus, a Fibre Channel connection, a Universal Serial Bus (USB), a PCIe Advanced Switching (PCIe-AS) bus, or the like. In another embodiment, the memory device 620 can be disposed on a data network 615, such as an Ethernet network, an Infiniband network, SCSI RDMA over a network 615, a storage area network (SAN), a local area network (LAN), a wide area network (WAN) such as the Internet, another wired and/or wireless network 615, or the like.

The computing device 610 can further comprise a non-transitory, computer readable storage medium 614. The computer readable storage medium 614 can comprise executable instructions configured to cause the computing device 610 (e.g., processor 611) to perform steps of one or more of the methods disclosed herein. In one embodiment, a subgroup selection circuit 650 can comprise hardware of a non-volatile and/or volatile memory element 623, computer executable program code of a device driver, firmware of a memory controller 626 and/or a memory media controller for a memory element 623, another electrical component, or the like. In one embodiment, a subgroup selection circuit 650 is integrated on a memory element 623 (e.g., an on-die subgroup selection circuit 650 and/or other integrated hardware).

According to various embodiments, a memory controller 626 can manage one or more memory devices 620 and/or memory elements 623, one or more of which can comprise an on-die subgroup selection circuit 650. The memory device(s) 620 can comprise recording, memory, and/or storage devices, such as solid-state storage device(s) and/or semiconductor storage device(s) that are arranged and/or partitioned into a plurality of addressable media storage locations. As used herein, a media storage location refers to any physical unit of memory (e.g., any quantity of physical storage media on a memory device 620). Memory units and/or regions can include, but are not limited to: pages, memory divisions, blocks, sectors, collections or sets of physical storage locations (e.g., logical pages, logical blocks), or the like.

A device driver and/or the memory controller 626, in certain embodiments, can present a logical address space 634 to the storage clients 616. As used herein, a logical address space 634 refers to a logical representation of memory resources. The logical address space 634 can comprise a plurality (e.g., range) of logical addresses. As used herein, a logical address refers to any identifier for referencing a memory resource (e.g., data), including, but not limited to: a logical block address (LBA), cylinder/head/sector (CHS) address, a file name, an object identifier, an I node, a Universally Unique Identifier (UUID), a Globally Unique Identifier (GUID), a hash code, a signature, an index entry, a range, an extent, or the like.

A device driver for the memory device 620 can maintain metadata 635, such as a logical to physical address mapping structure to map logical addresses of the logical address space 634 to media storage locations on the memory device(s) 620. A device driver can be configured to provide storage services to one or more storage clients 616. The storage clients 616 can include local storage clients 616 operating on the computing device 610 and/or remote storage clients 616 accessible via the network 615 and/or network interface 613. The storage clients 616 can include, but are not limited to: operating systems, file systems, database applications, server applications, kernel-level processes, user-level processes, applications, and the like.

A device driver can be communicatively coupled to one or more memory devices 620. The one or more memory devices 620 can include different types of memory devices including, but not limited to: solid-state storage devices, semiconductor storage devices, SAN storage resources, volatile memory devices, non-volatile memory devices, or the like. The one or more memory devices 620 can comprise one or more respective memory media controllers 626 and memory media 622. A device driver can provide access to the one or more memory devices 620 via a traditional block I/O interface 631. Additionally, a device driver can provide access to enhanced functionality through the SCM interface 632. The metadata 635 can be used to manage and/or track data operations performed through any of the Block I/O interface 631, SCM interface 632, cache interface 633, or other related interfaces.

The cache interface 633 can expose cache-specific features accessible via a device driver for the memory device 620. Also, in some embodiments, the SCM interface 632 presented to the storage clients 616 provides access to data transformations implemented by the one or more memory devices 620 and/or the one or more memory media controllers 626.

A device driver can present a logical address space 634 to the storage clients 616 through one or more interfaces. As discussed above, the logical address space 634 can comprise a plurality of logical addresses, each corresponding to respective media locations on one or more memory devices 620. A device driver can maintain metadata 635 comprising any-to-any mappings between logical addresses and media locations, or the like.

A device driver can further comprise and/or be in communication with a memory device interface 639 configured to transfer data, commands, and/or queries to the one or more memory devices 620 over a bus 625, which can include, but is not limited to: a memory bus of a processor 611, a peripheral component interconnect express (PCI Express or PCIe) bus, a serial Advanced Technology Attachment (ATA) bus, a parallel ATA bus, a small computer system interface (SCSI), FireWire, Fibre Channel, a Universal Serial Bus (USB), a PCIe Advanced Switching (PCIe-AS) bus, a network 615, Infiniband, SCSI RDMA, or the like. The memory device interface 639 can communicate with the one or more memory devices 620 using input-output control (IO-CTL) command(s), IO-CTL command extension(s), remote direct memory access, or the like.

The communication interface 613 can comprise one or more network interfaces configured to communicatively couple the computing device 610 and/or the memory controller 626 to a network 615 and/or to one or more remote, network-accessible storage clients 616. The storage clients 616 can include local storage clients 616 operating on the computing device 610 and/or remote storage clients 616 accessible via the network 615 and/or the network interface 613. The memory controller 626 is part of and/or in communication with one or more memory devices 620. Although FIG. 6 depicts a single memory device 620, the disclosure is not limited in this regard and could be adapted to incorporate any number of memory devices 620, a combination of one or more volatile memory devices 620 and one or more non-volatile memory devices 620, or the like.

The memory device 620 can comprise one or more elements 623 of memory media 622. In one embodiment, an element 623 of memory media 622 comprises a volatile memory medium 622, such as random-access memory (RAM), dynamic RAM (DRAM), synchronous DRAM (SDRAM), double data rate (DDR) SDRAM, static RAM (SRAM), thyristor RAM (T-RAM), zero-capacitor RAM (Z-RAM), or the like. In certain embodiments, an element 623 of memory media 622 comprises a non-volatile memory medium 622, such as ReRAM, Memristor memory, programmable metallization cell memory, phase-change memory (PCM, PCME, PRAM, PCRAM, ovonic unified memory, chalcogenide RAM, or C-RAM), NAND flash memory (e.g., 2D NAND flash memory, 3D NAND flash memory), NOR flash memory, nano random access memory (nano RAM or NRAM), nanocrystal wire-based memory, silicon-oxide based sub-10 nanometer process memory, graphene memory, Silicon-Oxide-Nitride-Oxide-Silicon (SONOS) memory, programmable metallization cell (PMC) memory, conductive-bridging RAM (CBRAM), magneto-resistive RAM (MRAM), magnetic storage media (e.g., hard disk, tape), optical storage media, or the like. Thus, the memory device 620 may rely, for example, on stored voltage levels or stored resistance levels. The one or more elements 623 of memory media 622, in certain embodiments, comprise storage class memory (SCM).

While legacy technologies such as NAND flash can be block and/or page addressable, storage class memory, in one embodiment, is byte addressable. In further embodiments, storage class memory can be faster and/or have a longer life (e.g., endurance) than NAND flash; can have a lower cost, use less power, and/or have a higher storage density than DRAM; or offer one or more other benefits or improvements when compared to other technologies. For example, storage class memory can comprise one or more non-volatile memory elements 623 of ReRAM, Memristor memory, programmable metallization cell memory, phase-change memory, nano RAM, nanocrystal wire-based memory, silicon-oxide based sub-10 nanometer process memory, graphene memory, SONOS memory, PMC memory, CBRAM, MRAM, and/or variations thereof.

While the non-volatile memory media 622 is referred to herein as “memory media,” in various embodiments, the non-volatile memory media 622 can more generally comprise one or more non-volatile recording media capable of recording data, which can be referred to as a non-volatile memory medium, a non-volatile storage medium, or the like. Further, the nonvolatile memory device 620, in various embodiments, can comprise a non-volatile recording device, a non-volatile memory device, a non-volatile storage device, or the like. Similarly, a nonvolatile memory element 623, in various embodiments, can comprise a non-volatile recording element, a non-volatile memory element, a non-volatile storage element, or the like.

The non-volatile memory media 622 can comprise one or more non-volatile memory elements 623, which can include, but are not limited to: chips, packages, planes, die, or the like. A non-volatile memory controller 626 can be configured to manage data operations on the nonvolatile memory media 622, and can comprise one or more processors, programmable processors (e.g., FPGAs), ASICs, micro-controllers, or the like. In some embodiments, the nonvolatile memory controller 626 is configured to store data on and/or read data from the nonvolatile memory media 622, to transfer data to/from the non-volatile memory device 620, and so on.

The non-volatile memory controller 626 can be communicatively coupled to the non-volatile memory media 622 by way of a bus 627. The bus 627 can comprise an I/O bus for communicating data to/from the non-volatile memory elements 623. The bus 627 can further comprise a control bus for communicating addressing, and other command and control information to the non-volatile memory elements 623. In some embodiments, the bus 627 can communicatively couple the non-volatile memory elements 623 to the non-volatile memory controller 626 in parallel. This parallel access can allow the non-volatile memory elements 623 to be managed as a group, forming a logical memory element 629. The logical memory element can be partitioned into respective logical memory units (e.g., logical pages) and/or logical memory divisions (e.g., logical blocks). The logical memory units can be formed by logically combining physical memory units of each of the non-volatile memory elements.

The non-volatile memory controller 626 can comprise and/or be in communication with a device driver executing on the computing device 610. A device driver can provide storage services to the storage clients 616 via one or more interfaces 631, 632, and/or 633. In some embodiments, a device driver provides a block-device I/O interface 631 through which storage clients 616 perform block-level I/O operations. Alternatively, or in addition, a device driver can provide a storage class memory (SCM) interface 632, which can provide other storage services to the storage clients 616. In some embodiments, the SCM interface 632 can comprise extensions to the block device interface 631 (e.g., storage clients 616 can access the SCM interface 632 through extensions or additions to the block device interface 631). Alternatively, or in addition, the SCM interface 632 can be provided as a separate API, service, and/or library. A device driver can be further configured to provide a cache interface 633 for caching data using the non-volatile memory system 602. A device driver can further comprise a non-volatile memory device interface 639 that is configured to transfer data, commands, and/or queries to the non-volatile memory controller 626 over a bus 625, as described above.

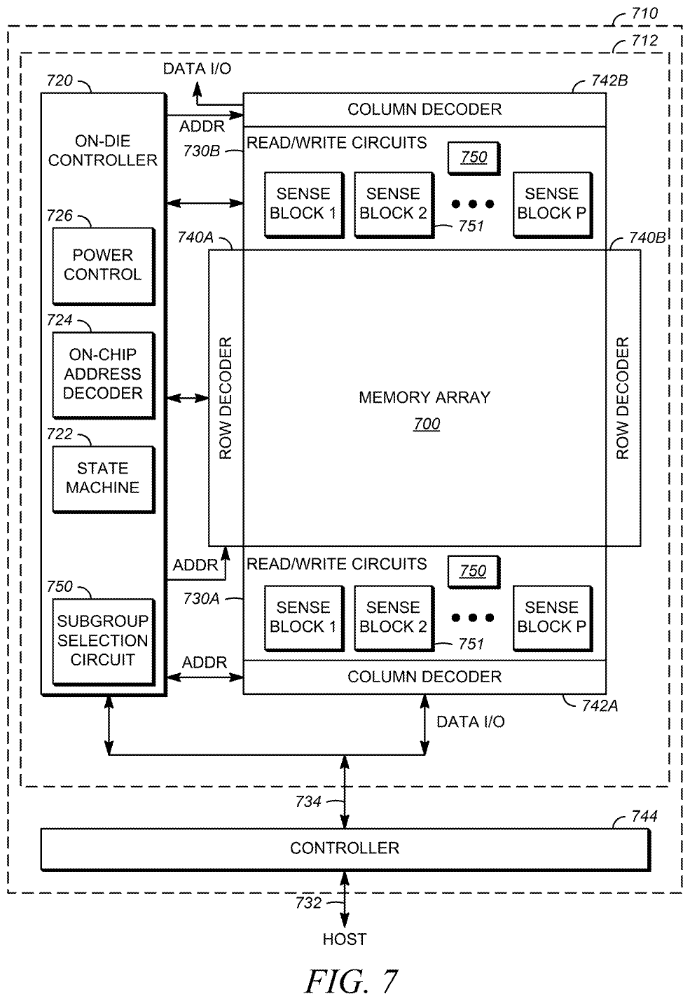

FIG. 7 is a schematic block diagram illustrating an embodiment of a non-volatile storage device 710, which can perform programming and verify operations as described herein. The non-volatile storage device 710 can include one or more memory die or chips 712 “memory die” comprises a block of semiconducting material on which a memory circuit is fabricated and, as used herein, also includes the memory circuit disposed thereon. The nonvolatile storage device 710 can be substantially similar to the computing device 610 described with reference to FIG. 6.

The memory die 712, in some embodiments, includes an array 700 (e.g., two-dimensional or three dimensional) of memory cells, an on-die controller 720, and read/write circuits 730A/730B. In one embodiment, access to the memory array 700 by the various peripheral circuits is implemented in a symmetric fashion, on opposite sides of the memory array 700, so that the densities of access lines and circuitry on each side are reduced by half. The read/write circuits 730A/730B, in a further embodiment, include multiple sense blocks 751 which allow a page of memory cells to be read or programmed in parallel.

The memory array 700, in various embodiments, is addressable by word lines via row decoder circuits 740A/740B and by bit lines via column decoder circuits 742A/742B. In some embodiments, a controller 744 is included in the same memory device 710 (e.g., a removable storage card or package) as the one or more memory die 712. Commands and data are transferred between the host and controller 744 via lines 732 and between the controller and the one or more memory die 712 via lines 734. One implementation can include multiple chips 712.

On-die controller 720, in one embodiment, cooperates with the read/write circuits 730A/730B to perform memory operations on the memory array 700. The on-die controller 720, in certain embodiments, includes a state machine 722, an on-chip address decoder 724, and a power control circuit 726. In one embodiment, the on-chip address decoder 724 and/or the power control circuit 726 can be part of and/or controlled by the controller 744. The on-die controller 720 an operate to select certain single tiers for certain program verify levels and multiple tiers for other program verify levels.

The state machine 722, in one embodiment, provides chip-level control of memory operations. The on-chip address decoder 724 provides an address interface to convert between the address that is used by the host or a memory controller to the hardware address used by the decoder circuits 740A, 740B, 742A, 742B. The power control circuit 726 controls the power and voltages supplied to the word lines and bit lines during memory operations. In one embodiment, the power control circuit 726 includes one or more charge pumps that can create voltages larger than the supply voltage. The state machine 722 can be used to count the bitscans and compare the result to the threshold value, which can be stored in the state machine 722. The state machine 722 can also trigger the program verify operation to skip to the next memory level verify operation when the bitscan count exceeds the threshold value.

In an embodiment, one or any combination of the on-die controller 720, state machine 722, power control circuit 726, on-chip address decoder 724, decoder circuit 742 A, decoder circuit 742B, decoder circuit 740 A, decoder circuit 740B, read/write circuits 730 A, read/write circuits 730B, and/or controller 744 can be referred to as one or more managing circuits or generally as a controller circuitry.

The program operations start with a select number of memory cells to be programmed to a first state (S1). At the end of a given program loop, a bit scan pass fail rate is compared to the TAG count of memory cells that are not yet programmed to their target state, i.e., their Vth is still less than VH. If this TAG count is less than the bit scan pass fail rate, then it means that most of the cells are programmed, and thus, the program is passed. Embodiments described herein propose to apply a similar operation but detect whether the memory cells are in the QPW state with VL<Vth<VH for the memory cells being subject to programming to S1. In an example embodiment when programming one thousand memory cells, then the detect QPW criterion is less than or equal to ninety or less than or equal to 85. The verify operation can also count the number of memory cells being programmed to S1 that have a voltage level Vth that is less than a VLVS criterion. In the case of one thousand memory cells, the VLVS criterion can be less than or equal to thirty memory cells or less than or equal to twenty-five memory cells. If one or both of these criteria are met, then subsequent VL verification can be skipped to save the time for the VL verify operations.

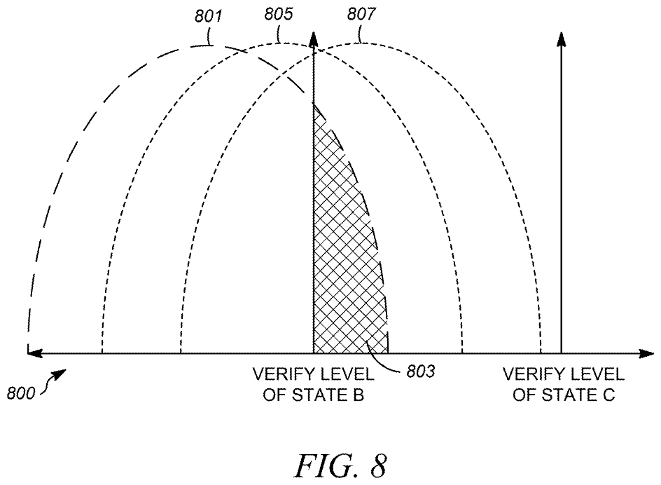

FIG. 8 shows a diagram 800 with a program bit count verify for a plurality of memory cells, which can verifying a first memory state, here shown as the State B, and a second memory state, here state C. While the states B and C are used to illustrate the present concept, it will be recognized that the other consecutive states can also use similar bit verify count principals. Voltage is represented on the abscissa with VH for a high voltage for a programmed level of a memory cell, which for example will be to the right of the voltage for state B, and VL for a low voltage for a programmed level of memory cell, which for example will be to the left of the voltage state B. A correctly programmed memory cell will have its Vth being greater than VH. The area under the curve represents the voltage levels of the memory cells collectively. The pulse 801 is applied to the memory cells and the bitscan count of the number of memory cells that exceed the voltage verify level of State B. This is represented in area 803 to the right of the voltage verify level of State B. If the bitscan count in area 803 does not exceed a threshold value, then the memory system will apply the next verify pulse 805. If the bitscan count in area 803 meets or exceeds a threshold value, then the memory system will skip the next verify pulse 805 and apply a verify pulse 807 beyond pulse 805. The verify process can skip at least one verify pulse. In an example embodiment, the verify process skips to pulses to verify the level of State C. In an example embodiment, if the memory cell is in QPW or if the sensed Vth is less than VL, then the subsequent verify pulses for that memory cell are skipped.

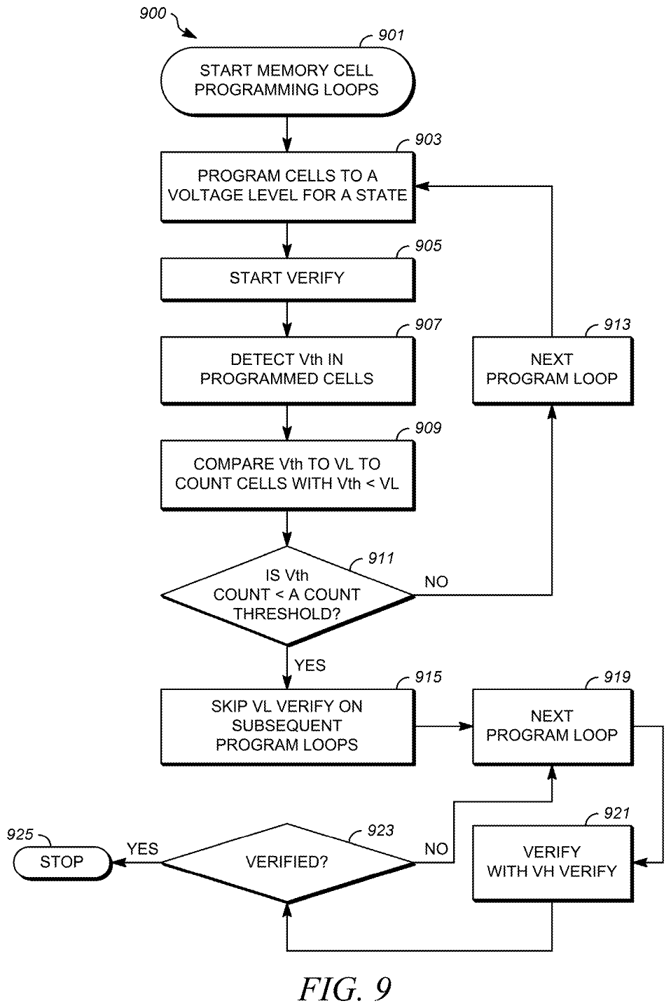

FIG. 9 shows a flow chart 900 of an algorithm that is able to reduce tPROG in a memory device. The process steps described herein can be stored as instructions in the memory controller. At step 901, the memory starts a memory programming operation to program data states into a plurality of memory cells, which can be represented as voltage levels in the memory cells. The programming operation includes using program loops, which apply programming voltage signals and then verify the voltage levels being stored in the memory cells. The examples described herein can shorten the time required to execute the program loop by shortening the verify times.

At step 903, a programming voltage is applied to memory cells for a program time period. This sets voltage levels in the memory cells, which can set the states of the memory cells. At step 905, the verify process starts and includes verifying the voltage levels in the programmed memory cells. At step 907, the voltage level Vt in the memory cell is detected.

At step 909, the detected voltage level Vth is compared to VL, which is the low voltage level a memory cell needs to cross to reach closer to its target programmed state. That is a memory cell has a range of voltages from VL to VH at each program level. When Vth>VH, then memory cell is classified as being programmed to that program level or state. If VL<Vth<VH, then memory cell is classified as being in Quick Pass Write state (QPW), i.e. it is close enough to be fully programmed, but is not yet fully programmed. If Vth<VL, then memory cell is classified as being unprogrammed. The comparison of detected Vth to VL results in a count of the number of memory cells with Vth less than VL. At decision step 911, it is determined if the count of the number of memory cells with Vth less than VL meets a count threshold value, which can be set in the memory controller and be based on experimental results. If the count of memory cells less than Vth is more than the count threshold (i.e., the answer at decision step 911 is no), then the process moves to the next programming loop 913 and the memory cells are programmed again at step 903 with an incrementally increased programming voltage. Once again, at step 905, a full verify operation is performed, and then the method continues to steps 907 and 909. If the count meets or is less than the count threshold value (i.e., the answer at decision step 911 is yes), the process moves to step 915.

At decision step 915, the memory controller is configured to skip the VL verify operation on subsequent program loops. This can be a flag set in the memory controller. At step 919, the next program loop begins with a program voltage being applied to the memory cells being programmed. At step 921, verify of the high voltage VH is performed. At decision step 923, a check of whether the memory cells are verified is performed. If the answer at decision step 923 is no, then the method returns to step 919 to begin the next program loop. If the answer at decision step 923 is yes, then this programming loop ends at 925. If there are addition programming loops, then the process returns to step 903 for the next programming level.

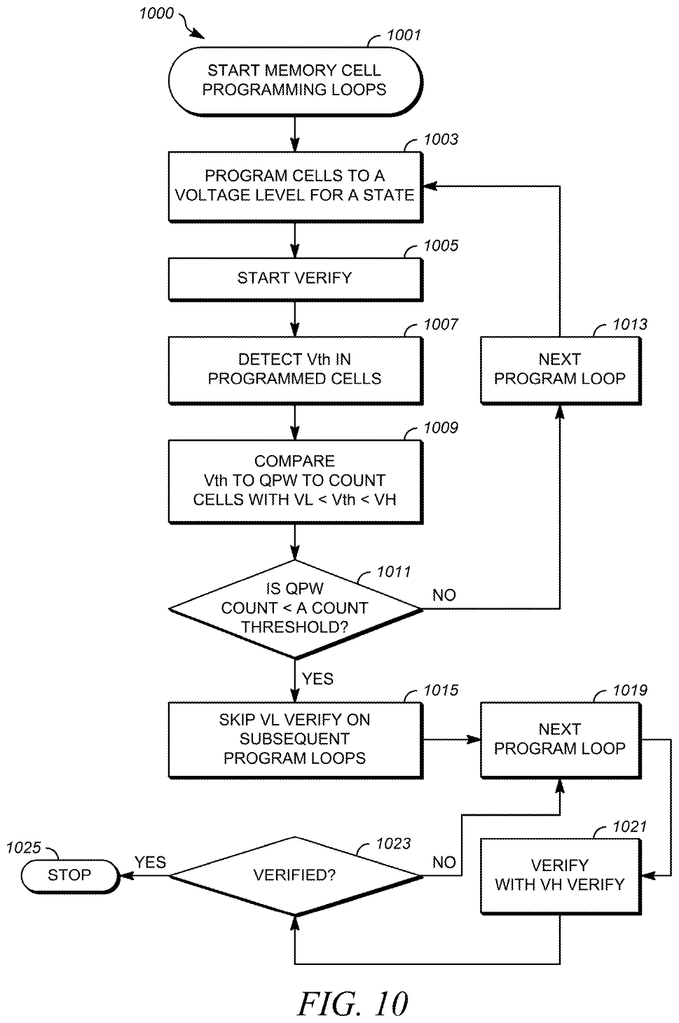

FIG. 10 shows another flow chart 1000 of an algorithm to reduce tPROG in a memory device. The process steps described herein can be stored as instructions in the memory controller. At step 1001, the memory starts a memory programming operation to program data states, which can be represented as voltage levels, into the memory cells. The programming operation includes using program loops, which apply programming voltage signals and then verify the voltage levels being stored in the memory cells.

At step 1003, a programming voltage is applied to memory cells for a program time period. This sets voltage levels in the memory cells, which can set the states of the memory cells. At step 1005, the verify process starts and includes verifying the voltage levels in the programmed memory cells. At step 1007, the voltage level Vt in the memory cell is detected.

At step 1009, a determination is made of the number of memory cells that are in a QPW state. An example of QPW is when the detected voltage level Vth is between the VH and VL. A memory cell is programmed correctly when the Vth>VH. When VL<Vth<VH. the voltage in the memory cell Vth has reached a stored voltage level close enough to the target state, e.g., greater than VH, so that certain verify operations in the subsequent programming loops can be skipped.

At decision step 1011, it is determined if the count of the number of memory cells that are in QPW meets a QPW count threshold value. The QPW count threshold value can be set in the memory controller and be based on experimental results. If the answer at decision step 1011 is no, then the process moves to the next programming loop 1013, and the memory cells are programmed at step 1003 according to the next programming loop. A full verify operation is then performed at step 1005, and steps 1007 and 1009 are repeated. If the count meets or is less than the QPW count threshold value (i.e., the answer at decision step 1011 is yes), then the process advances to step 1015.

At step 1015, the controller is configured to skip the VL verify operation for subsequent verify operation. This can be a flag set in the memory controller. This saves the time that the VL verify is performed.

At step 1019, the next program loop is performed with a program voltage application to the memory cells. At step 1021, verify of the high voltage VH is performed.

At decision step 1023, a check of whether the memory cells are verified is performed. If the answer at decision step 1023 is no, then the process returns to step 1019, and a program operation the memory cells is repeated with the next program loop. If the answer at decision step 1019 is yes, then this programming loop ends at 1025. If there are addition programming loops, then the process returns to step 1003 for the next programming level

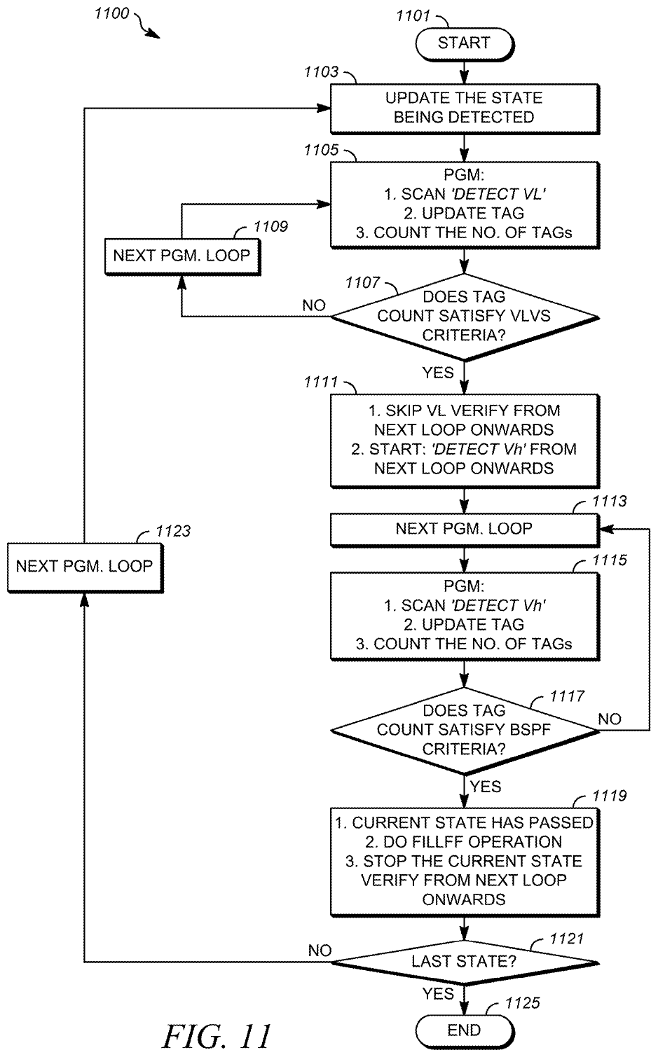

FIG. 11 shows yet another flow chart 1100 of an algorithm to reduce tPROG in a memory device. The process steps described herein can be stored as instructions in the memory controller. At step 1101, the memory starts a memory programming operation. At step 1103, the memory state being detected is updated. The memory state can be the parameters associated with a particular voltage level to that the memory cells are to be programmed. The parameter can be the voltage level, e.g., Vth.

At step 1105, a write operation is performed, which includes applying a program electrical signal to the memory cells and a verify operation to verify the state of the memory cells after applying the program signal. Verification is performed by detecting the voltages Vth in the memory cells. If the Vth is less than VL (i.e., the low voltage level of a programmed memory cell) for a particular memory cell, then the memory cell is updated as a TAG. The number of TAGs is counted to generate a TAG count.

At decision step 1107, a comparison is made of the TAG count compared to a low voltage VLVS criterion. In one embodiment, the VLVS criterion is a tag count of less than or equal to thirty. If the TAG does not meet the VLVS criterion (the answer at decision step 1007 is no), then the process moves to the next program loop at 1109 and returns to the programming step 1105. If the TAG counts satisfies the VLVS criterion (the answer at decision step 1107 is yes), then the process moves to step 1111.

At step 1111, the memory controller is configured to skip the VL verification steps for subsequent program loops. The verification in the subsequent program loops can still detect the high voltage VH in the verify operations. At step 1113, the next program loop is initiated.

At step 1115, the programming voltage levels are applied to the memory cells to be programmed. Verification of the programmed level is then performed by detecting the voltage level Vth in the memory cells. The TAG value for the memory cells undergoing programming is updated when the Vth<VH for the cells. A count of the TAG is performed. The TAG count indicates how many cells are failing to get programmed to their target state.

At decision step 1117, it is determined if the TAG count for VH verify satisfies the bit scan pass fail (BSPF) criterion. The BSPF criteria can be a numerical value that determines how many bits may fail to be programmed correctly before a memory cell programming operation fails. For example, a BSPF criteria of fifty would allow up to fifty memory cells to fail being programmed correctly before the programming of that memory state for select memory cells to fail. If the answer at decision step 1117 is no, then the process returns to step 1113. If the BSPF criterion is met by the VH count (i.e., the answer at decision step 1117 is yes), then the current program state has passed the verify operation, and the process proceeds to step 1119. At step 1119, end processes (FILLFF) for the verification of the current states of the memory cells are performed. The verify operations are then ended for the subsequent program loops.

At decision step 1121, it is determined if this is the last state to program the memory cells. If it is not the last state, then the state is updated to the next sequential state, the next program loop is designated at 1123 for this new state, and the process starts again at 1103 for the next state.

At least some of the above systems and methods provide a time reduction in tPROG, which is the time it takes to program memory cells to the correct levels by eliminating some of the VL verification times. The program loops can skip VL verify using the counting of the number of memory cells with the verified voltage Vth is less than VL or when the memory cells are in QPW, e.g., VL<Vth<VH. It is believed that there can be 142 μs (micro second) time savings in tPROG. This can provide at least a 0.23 MB/s gain per memory state.

In some embodiments, there can be multifold tPROG improvement with each additional verify skip, e.g., VLVS as described herein. In one example, it has been found that with two VL verify skips per memory state, tPROG can be reduced by 276 μs (142 μs+134 μs), which can result in a 0.45 MB/s gain. In another example, with three VL verify skips per memory state, tPROG can be reduced by 418 μs (142 μs+134 μs+142 μs), which can result in a 0.68 MB/s gain.

In the process 1100, detect QPW and detect VL are not followed by the FILLFF operation, this reduces the time cost to run detect QPW and detect VL.

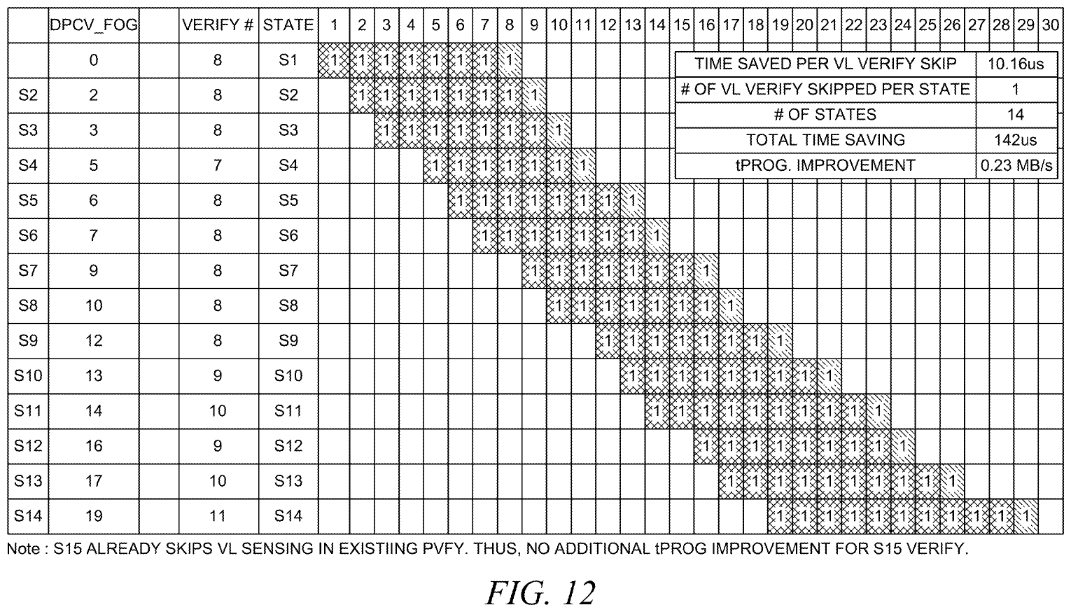

FIG. 12 shows a program verify schematic diagram 1200 of the programming of sixteen states (S1-S15 plus erase) of memory cells. The erase need not be verified during a program or write operation. In this example, each program state has one program loop that does not require the verification of the Vth against VL. The last program loop in each state need only verify VH. For an example memory, each low voltage verification skip saves about ten microseconds (μs) with one skip per state. This example has fourteen states for a time savings of about one hundred forty microseconds and a tPROG of 0.23 MB/s.

The memory device programming diagram 1200 shows all of the program and verify operations for each states S1-S14 in the highlighted fields, e.g., for S1 this is programming loops 1-8, with loops 1-7 including verify operations of both VL and VH with programming loop 8 not including the VL verify operation. State S2 includes programming loops 2-9 with programming loops 2-8 including both VL and VH verify operations and programming loop 9 only including VH verify operation. State S3 includes programming loops 3-10 with programming loops 3-9 including both VL and VH verify operations and programming loop 10 only including VH verify operations. State S4 includes programming loops 5-11 with programming loops 5-10 including both VL and VH verify operations and programming loop 11 only including VH verify operation. State S5 includes programming loops 6-13 with programming loops 6-12 including both VL and VH verify operations and programming loop 13 only including VH verify operations. State S6 includes programming loops 7-14 with programming loops 7-13 including both VL and VH verify operations and programming loop 14 only including VH verify operation. State S7 includes programming loops 9-16 with programming loops 9-15 including both VL and VH verify operations and programming loop 16 only including VH verify operations. State S8 includes programming loops 10-17 with programming loops 10-16 including both VL and VH verify operations and programming loop 16 only including VH verify operation. State S9 includes programming loops 12-19 with programming loops 12-18 including both VL and VH verify operations and programming loop 19 only including VH verify operations. State S10 includes programming loops 13-21 with programming loops 13-20 including both VL and VH verify operations and programming loop 21 only including VH verify operation. State S11 includes programming loops 14-23 with programming loops 14-22 including both VL and VH verify operations and programming loop 23 only including VH verify operations. State S12 includes programming loops 16-24 with programming loops 16-23 including both VL and VH verify operations and programming loop 34 only including VH verify operation. State S13 includes programming loops 17-26 with programming loops 17-25 including both VL and VH verify operations and programming loop 26 only including VH verify operations. State S14 includes programming loops 19-29 with programming loops 19-28 including both VL and VH verify operations and programming loop 29 only including VH verify operations.

It is believed that existing DETECT algorithms only identify & count the number of unprogrammed cells (Vth<VH). The number of these memory cells that are in QPW and and that satisfy Vth<VL is not a factor. The presently described embodiments may include a programming algorithm that introduces an intermediate step (either DETECT QPW or DETECT VL) and identifies the number of cells in QPW or with Vth<VL. This count information is then compared against VLVS criteria, e.g., distinct count totals for QPW and less than VL. Until VLVS criteria is satisfied, DETECT VL or DETECT QPW is performed and until then DETECT VH is not performed. Also, both VL and VH sensing are done until VLVS criteria gets satisfied. Once VLVS is satisfied, VL sensing is no longer needed. Thus, the following programming loops skip VL sensing.

The volatile memory device can use a scan operation and a detect operation to reduce the time spent to verify the state of memory cells. The scan operation operates to determine the state of a memory cell of group of memory cells being part of a verify in programming, e.g., during a programming loop. The scan operation can determine the cell voltage level, e.g., the low voltage (VL). The scan operation can determine if the cell is in a QPW state, e.g., the cells with their voltage (Vth) between the VL and VH. The detect operation determines whether the subsequent VL sensing is to be skipped based on the count of memory cells that exceed VL and those in QPW.

The present description with TAG designations for verification states of memory cells undergoing a write operation or programming operation. The TAG designations and their count can be stored in buffer (memory) in the memory controller. During VH detect operations, a TAG can be set at zero or one for each memory cell being programmed. A TAG is set to zero with the memory cells to be programmed to the desired state and are completed programmed or are cells that belong to other states. A TAG is set to one with the memory cells to be programmed to the desired state but still have not yet reached the desired state. During VL detect operations, a TAG can be set at zero or one for each memory cell being programmed. A TAG is set to zero with the memory cells to be programmed to the desired state and in a QPW level, are completed programmed or are cells that belong to other states. A TAG is set to one with the memory cells to be programmed to the desired state but still have Vth<VL. During QPW detect operations, a TAG can be set at zero or one for each memory cell being programmed. A TAG is set to zero with the memory cells to be programmed to the desired state, are completed programmed or are cells that belong to other states or still Vth<VL. A TAG is set to one with the memory cells to be programmed to the desired state but still have Vth less than VH and greater than VL.

In some embodiments, the time required for wordline (WL) and bitline (BL) setup while switching to the next state verify cannot be skipped. In this instance, time may be mainly saved in the sense (SEN) pre-charge and sense operation. The time to reach a stable state on the wordline can mean the time for the desired voltage to be reached from the near end of the wordline to a far end of the wordline. Overall, the saved time can translate to approximately the same as the time consumed by the IQPW_CLK (VH sensing). In some embodiments, the time savings can be about 10 μs, +/−0.1 μs, 0.2 μs or up to 1.0 μs.

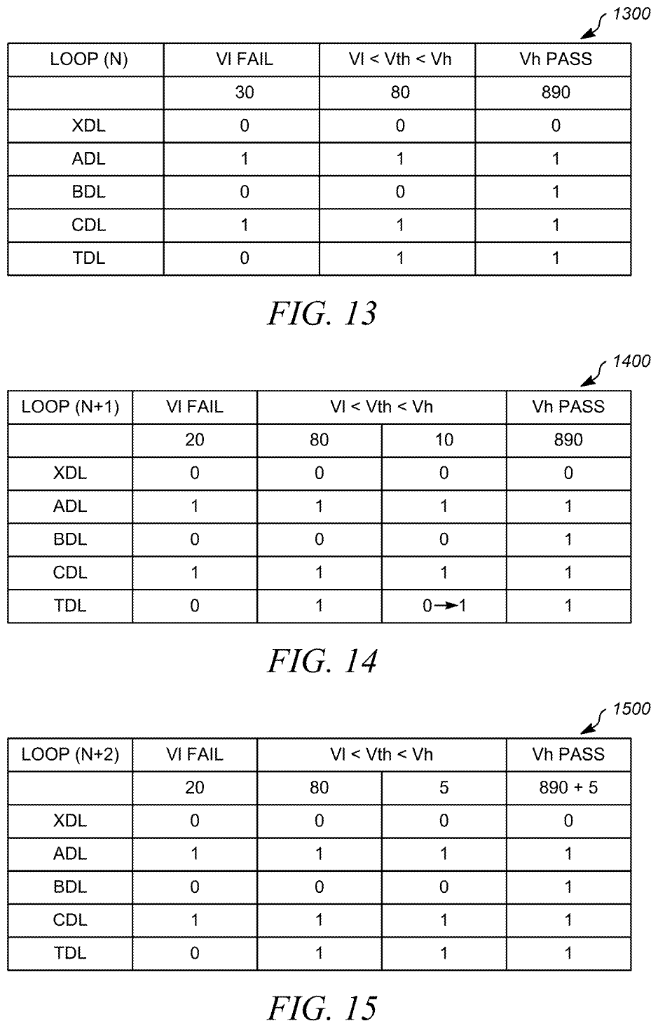

Referring now to FIGS. 13-15, graphs 1300, 1400, 1500 of memory states are shown during memory verification for three programming loops, namely, programming loop N (FIG. 13), programming loop N+1 (FIG. 14), and programming loop N+2 (FIG. 15). Graph 1300 shows states of the memory cells for an N loop with a TAG count of memory cells that are less than VL in the second column, that are in the QPW state (i.e., VL<Vth<VH) in the third column, and VH pass in the fourth column. The combination of values stored in an “X” data latch (XDL), an “A” data latch (ADL), a “B” data latch (BDL), a “C” data latch (CDL) represents the state of the memory cell. This combination will be present in these data latches at the beginning of program operation. One additional “T” data latch (TDL) is used to store the VL Sensing result. This example shows one thousand memory cells. It will be understood that having more or fewer memory cells is within the scope of the present disclosure. Here, thirty memory cells fail the first test of Vth>VL, which results in a 0 being written to TDL. Eighty memory cells are in the QPW states which causes the TDL state to change to a 1 from 0 relative to the VL fail state. Eight hundred and ninety of the memory cells have Vth>VH, so they are programmed correctly and the BDL state changes to 1 from 0 relative to the QPW state values in the data latches. The values of the memory cells are the TAG counts for their three states. The TAG count for the testing of VL should be less than thirty in this case to trigger the low voltage verify skip operation. That is, the count value threshold is set at 31. Accordingly, the number of memory cells that have a sensed voltage (Vth) less than or equal to VL, must be thirty or less to trigger the VL verify skip operation. However, the memory controller may overprogram at least some of the memory cells after entering the verify skip.

The overprogram may be the result of some cells with voltage level (Vth) less than VL enter the QPW state during the next program loop. The VL verify skip operation skips VL sensing after the loop N. And at loop N+1, some memory cells, here shown as 10 in graph 1400 are added to the QPW state. But the data latch TDL is not updated and these memory cells are not identified as in the QPW state. As a result, a full program pulse (e.g., bit line BL=VSS), is applied to the N+2 program loop and the memory cells added to the QPW state may be overprogrammed.

The present disclosure addresses the possible overprogram by limiting the number of full program pulses to be applied once one of the VLVS criteria is met. Graph 1300 shows results from a process of when VLVS criterion is satisfied after loop (N). VL verify is to be skipped from loop (N+1) onwards. A full program limit is set so that a single full program is performed after the VLVS criterion is met. Thus, a single full program will be applied during loop (N+1). And during SETDL, TDL=1 is updated along with SDL for the state for which VL Verify is being skipped.

Graph 1400 shows the results of program loop N+1. A single full program pulse is applied during loop (N+1). TDL is updated to 1 during SETDL operation during program verify of loop (N+1) for all the memory cells which belong to the state for which VL Verify is being skipped. The TDL value for these memory cells changes from 0 to 1. A new SETDL operation is set to be used during program verify of the next programming loop (N+1). This results in additional time being added. The time can be about 0.56 μs, e.g., 0.56 μs before next RWL_CLK starts. Another full program pulse is not applied to the memory cells that transition to the QPW state.

Graph 1500 shows the results of program loop N+2. Some memory cells, here shown as 5, transition from the QPW to VH pass (full programmed). The data latch TDL has already been updated during program verify of the previous programming loop (N+1). The data latch value TDL for these memory cells will continue to remain set to 1 until the end of programming. There is no need to set TDL from PVFY of loop (N+2) onwards. After programming loop N+2, the setting of the data latches (e.g., SETDL operation) from programming loop (N+2) onwards goes back to a conventional operation. In operation, the program verify, where TDL=1 is updated the present description, a timing penalty may be added, e.g., 0.56 μs is added. This reduces that time savings to about 9.6 μs time saving during that VL sensing skip as opposed to some embodiments that may result in a time savings of about 10.16 μs. However, this timing penalty occurs only one time, e.g., if ‘K’ VL verifies are skipped for a given state, then ‘K−1’ VL sense skips will save 10.16 μs per skip and only ‘1’ VL sense skip will save 9.6 μs (about 0.56 us less saving because of TDL=1 update time consumption).

Some embodiments described herein can be simple to implement, and merely require register transfer level (RTL) changes and do not require changes in the fabrication of the non-volatile memory circuitry layout. The RTL changes include two extra AND operations (one for each detect operation, i.e. QPW and VL). The RTL changes can include an extra step to update TDL during SETDL:TDL=TDL SEN. The changes can further include one modification in DETECT algorithm (to compare the count against VLVS criterion). The RTL changes can include changes to the scan operations, the detection algorithm, the parameters and the criteria. The scan operations can be changed to include (1) detect VL to identify memory cells to be programmed that still have their state Vth<VL and/or (2) detect QPW to identify memory cells to be programmed that still have their state Vth that satisfies VL<Vth<VH.

Computer program code for carrying out operations for aspects of the present disclosure can be written in any combination of one or more programming languages, including an object oriented programming language such as Python, Java, Smalltalk, C++, C#, Objective C, or the like, conventional procedural programming languages, such as the “C” programming language, scripting programming languages, and/or other similar programming languages. The program code can execute partly or entirely on one or more of a user's computer and/or on a remote computer or server over a data network or the like. A component, as used herein, comprises a tangible, physical, non-transitory device. For example, a component can be implemented as a hardware logic circuit comprising custom VLSI circuits, gate arrays, or other integrated circuits; off-the-shelf semiconductors such as logic chips, transistors, or other discrete devices; and/or other mechanical or electrical devices. A component can also be implemented in programmable hardware devices such as field programmable gate arrays, programmable array logic, programmable logic devices, or the like. A component can comprise one or more silicon integrated circuit devices (e.g., chips, die, die planes, packages) or other discrete electrical devices, in electrical communication with one or more other components through electrical lines of a printed circuit board (PCB) or the like. Each of the modules described herein, in certain embodiments, can alternatively be embodied by or implemented as a component.

A circuit or circuitry, as used herein, comprises a set of one or more electrical and/or electronic components providing one or more pathways for electrical current. In certain embodiments, a circuit can include a return pathway for electrical current, so that the circuit is a closed loop. In another embodiment, however, a set of components that does not include a return pathway for electrical current can be referred to as a circuit (e.g., an open loop). For example, an integrated circuit can be referred to as a circuit regardless of whether the integrated circuit is coupled to ground (as a return pathway for electrical current) or not. In various embodiments, a circuit can include a portion of an integrated circuit, an integrated circuit, a set of integrated circuits, a set of non-integrated electrical and/or electrical components with or without integrated circuit devices, or the like. In an embodiment, a circuit can include custom VLSI circuits, gate arrays, logic circuits, or other integrated circuits; off-the-shelf semiconductors such as logic chips, transistors, or other discrete devices; and/or other mechanical or electrical devices. A circuit can also be implemented as a synthesized circuit in a programmable hardware device such as field programmable gate array, programmable array logic, programmable logic device, or the like (e.g., as firmware, a netlist, or the like). A circuit can comprise one or more silicon integrated circuit devices (e.g., chips, die, die planes, packages) or other discrete electrical devices, in electrical communication with one or more other components through electrical lines of a printed circuit board (PCB) or the like. Each of the modules described herein, in certain embodiments, can be embodied by or implemented as a circuit.

By way of introduction, the following brief definitions are provided for various terms used in this application. Additional definitions will be provided in the context of the discussion of the figures herein. As used herein, “exemplary” can indicate an example, an implementation, and/or an aspect, and should not be construed as limiting or as indicating a preference or a preferred implementation. Further, it is to be appreciated that certain ordinal terms (e.g., “first” or “second”) can be provided for identification and ease of reference and may not necessarily imply physical characteristics or ordering. Therefore, as used herein, an ordinal term (e.g., “first,” “second,” “third”) used to modify an element, such as a structure, a component, an operation, etc., does not necessarily indicate priority or order of the element with respect to another element, but rather distinguishes the element from another element having a same name (but for use of the ordinal term). In addition, as used herein, indefinite articles (“a” and “an”) can indicate “one or more” rather than “one.” As used herein, a structure or operation that “comprises” or “includes” an element can include one or more other elements not explicitly recited. Thus, the terms “including,” “comprising,” “having,” and variations thereof signify “including but not limited to” unless expressly specified otherwise. The terms “a,” “an,” and “the” also refer to “one or more” unless expressly specified otherwise. Further, an operation performed “based on” a condition or event can also be performed based on one or more other conditions or events not explicitly recited. As used in this application, the terms “an embodiment,” “one embodiment,” “another embodiment,” or analogous language do not refer to a single variation of the disclosed subject matter; instead, this language refers to variations of the disclosed subject matter that can be applied and used with a number of different implementations of the disclosed subject matter. An enumerated listing of items does not imply that any or all of the items are mutually exclusive and/or mutually inclusive, unless expressly specified otherwise.

Aspects of the present disclosure are described below with reference to schematic flowchart diagrams and/or schematic block diagrams of methods, apparatuses, systems, and computer program products according to embodiments of the disclosure. It will be understood that each block of the schematic flowchart diagrams and/or schematic block diagrams, and combinations of blocks in the schematic flowchart diagrams and/or schematic block diagrams, can be implemented by computer program instructions. These computer program instructions can be provided to a processor of a computer or other programmable data processing apparatus to produce a machine, such that the instructions, which execute via the processor or other programmable data processing apparatus, create means for implementing the functions and/or acts specified in the schematic flowchart diagrams and/or schematic block diagrams block or blocks.

It should also be noted that, in some alternative implementations, the functions noted in the block can occur out of the order noted in the figures. For example, two blocks shown in succession can, in fact, be executed substantially concurrently, or the blocks can sometimes be executed in the reverse order, depending upon the functionality involved. Other steps and methods can be conceived that are equivalent in function, logic, or effect to one or more blocks, or portions thereof, of the illustrated figures. Although various arrow types and line types can be employed in the flowchart and/or block diagrams, they are understood not to limit the scope of the corresponding embodiments. For instance, an arrow can indicate a waiting or monitoring period of unspecified duration between enumerated steps of the depicted embodiment.

As used herein, a “memory cell” comprises a hardware component that may store a single state. The memory cell may comprise a volatile or a non-volatile memory cell. The state stored in memory cell may represent one of various types of values, such as a single-bit value or a multi-bit value

In the preceding detailed description, reference is made to the accompanying drawings, which form a part thereof. The foregoing summary is illustrative only and is not intended to be in any way limiting. In addition to the illustrative aspects, embodiments, and features described above, further aspects, embodiments, and features will become apparent by reference to the drawings and the following detailed description. The description of elements in each figure can refer to elements of proceeding figures. Like numbers can refer to like elements in the figures, including alternate embodiments of like elements.

The foregoing detailed description of the invention has been presented for purposes of illustration and description. It is not intended to be exhaustive or to limit the invention to the precise form disclosed. Many modifications and variations are possible in light of the above teachings. The described embodiments were chosen in order to best explain the principles of the invention and its practical application, to thereby enable others skilled in the art to best utilize the invention in various embodiments and with various modifications as are suited to the particular use contemplated. It is intended that the scope of the invention be defined by the claims appended hereto.

We claim:

1. An apparatus, comprising:
a plurality of volatile memory cells configured to be programmed to multiple states;
a memory controller operably connected to the plurality of memory cells and configured to:
program the plurality of memory to at least one of the multiple states; and
verify a state of the programmed memory cells,
wherein verify the state of the programmed memory cells includes:
scan the plurality of memory cells to detect the voltage level of the cell, and
compare the scanned voltage level against a low voltage verify skip criterion for at less than a high voltage level and if the low voltage verify skip criterion is met stop verify for the low voltage and continue verify for a high voltage criterion, and if the low voltage verify skip criterion is not met continue verify for the low voltage.

2. The apparatus of claim 1, wherein the low voltage verify skip criterion includes the sensed voltage of the memory cell being less than a VL level in the to be programmed memory cell.

3. The apparatus of claim 2, wherein the memory controller is configured to program the plurality of memory cells at any of the multiple states to store data therein using multiple programming loops and to skip subsequent program loops after the low voltage verify skip criterion is met.

4. The apparatus of claim 3, wherein the memory controller is configured to skip subsequent program loops to save time in tPROG by not performing low voltage verify when the low voltage verify skip criterion is met or wherein the low voltage verify skip reduces tPROG by at least 10 μs per state.

5. The apparatus of claim 1, wherein the low voltage verify skip criterion includes the sensed voltage of the memory cell being in a quick pass write level.

6. The apparatus of claim 5, wherein the low voltage verify skip criterion is the sensed voltage of the memory cell being greater than low voltage VL of the program state and less than the high voltage VH of program state.

7. The apparatus of claim 6, wherein the memory controller is configured to program the plurality of memory cells at any of the multiple states to store data therein using multiple programming loops and to skip subsequent program loops after the low voltage verify skip criterion is met.

8. The apparatus of claim 7, wherein the memory controller is configured to skip subsequent program loops to save time in tPROG by not performing low voltage verify when the low voltage verify skip criterion is met.

9. The apparatus of claim 8, wherein the low voltage verify skip reduces tPROG by at least 10 μs per state.

10. The apparatus of claim 8, wherein the memory controller skips a last programming loop of each memory cell state during verify.

11. The apparatus of claim 1, wherein the memory controller is configured to conduct a bit scan pass fail rate on the programmed memory cells after the low voltage verify skip is triggered or the memory cells are all fully programmed.

12. A nonvolatile memory control method, comprising:
programming memory cells to a state;
verifying stored values programmed into the memory cells including:
detecting a low voltage sensing count from the memory cells being programmed with the low voltage being as a low tail of a voltage distribution for the state; and
comparing the low voltage sensing count to a low voltage verify skip criterion when the criterion is not met moving on to the next programming loop with no verification change and when the criterion is met moving on to the next programming loop with and skipping any subsequent low voltage verify and using high voltage verifying in place of detecting the low voltage sensing count.

13. The method of claim 12, wherein detecting includes detecting quick-pass-write cells from the memory cells to produce a quick-pass-write cell count to be used as the low voltage sensing count.

14. The method of claim 13, wherein the low voltage skip criterion is a number of cells in the quick pass write level and when the low voltage sensing count meets or exceeds number of cells in the quick pass write level, then the criterion is met.

15. The method of claim 13, wherein verifying includes conducting a pass fail bit scan verify after the high voltage verifying.

16. The method of claim 12, wherein detecting includes detecting low voltage cells from the memory cells with voltage level less than a state low voltage and wherein comparing includes the criterion being a number of memory cells being below a low voltage tail for a program state.

17. The method of claim 12, wherein skipping any subsequent low voltage verify includes skipping verify of at least a last programming loop for two or more programming loops for a single memory cell programming state.

18. A nonvolatile memory program verify method, comprising:
programming memory cells to a state; and
verifying the state of the programmed memory cells, wherein verifying the state of the programmed memory cells includes:
scanning the plurality of memory cells to detect the voltage level of the memory cells;
comparing the scanned voltage level against a low voltage verify skip criterion for at less than a high voltage level;
counting a number of memory cells that pass the low voltage verify skip criterion to produce a low voltage verify skip count for the state; and
comparing the low voltage verify skip count to a count threshold and if the low voltage verify count is less than the count threshold, stop verifying memory cell program for the low voltage and continuing verify for a high voltage.

19. The method of claim 18, wherein verifying the state of the programmed memory cells includes continuing to verify for both for the low voltage and the high voltage when the count threshold is exceeded.

20. The method of claim 19, wherein verifying the state of the programmed memory cells includes skipping verify of at least a last programming loop for two or more programming loops for a single memory cell programming state.
